(19) United States
(12) Patent Application Publication
(10) Pub. No.: US 2025/0366040 A1
(43) Pub. Date: Nov. 27, 2025

(54) SEMICONDUCTOR STRUCTURES AND METHODS OF FORMING THE SAME

(71) Applicant: Taiwan Semiconductor Manufacturing Company, Ltd., Hsin-Chu (TW)

(72) Inventors: Yuan Tsung Tsai, Tainan City (TW); Wei Che Tsai, Pingtung City (TW); Huei Tang Wang, Taoyuan County (TW); Ying Ming Wang, Tainan City (TW); Syue Yi Lin, Kaohsiung City (TW); Shih-Hao Chen, Hsinchu County (TW)

(21) Appl. No.: 18/673,860

(22) Filed: May 24, 2024

(51) Int. Cl. H01L 29/423; H01L 21/027; H01L 21/311; H01L 21/8234; H01L 27/088; H01L 29/06; H01L 29/66; H01L 29/775; H01L 29/786

(52) U.S. Cl. CPC H10D 30/6735; H01L 21/0273; H01L 21/31144; H10D 30/014; H10D 30/43; H10D 30/6757; H10D 62/115; H10D 62/121; H10D 64/021; H10D 84/013; H10D 84/0135; H10D 84/0151; H10D 84/038; H10D 84/83

(57) ABSTRACT

A method includes forming a fin-shaped active region protruding from a substrate and having a uniform width, wherein, when viewed from top, the fin-shaped active region comprises a first segment having substantially straight sidewalls and a second segment immediately adjacent to the first segment and having curved sidewalls; forming a gate structure over the second segment of the fin-shaped active region; replacing the first segment of the fin-shaped active region with an isolation structure; and forming source/drain features coupled to the second segment of the fin-shaped active region.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, aggressive scaling down of IC dimensions has resulted in densely spaced features. Multi-gate devices, such as fin field-effect transistors (FinFETs) and gate-all-around (GAA) transistors, have been introduced in an effort to improve gate control by increasing gate-channel coupling, reduce OFF-state current, and reduce short-channel effects (SCEs). A FinFET has an elevated channel wrapped by a gate on more than one side (for example, the gate wraps a top and sidewalls of a “fin” of semiconductor material extending from a substrate). A GAA transistor has a gate structure that can extend, partially or fully, around a channel region to provide access to the channel region on two or more sides. The channel region of a GAA transistor may be formed from nanowires, nanosheets, or other nanostructures and for that reasons, and thus, a GAA transistor may also be referred to as a nanostructure transistor, a nanowire transistor, or a nanosheet transistor. The three-dimensional structure of the multi-gate devices allows them to be aggressively scaled while maintaining gate control and mitigating SCEs. A fin-shaped active region will be isolated from adjacent fin-shaped active regions by isolation features. The formation of the isolation features may involve performing processes at elevated temperature. With ever-decreasing device sizes, variations between the isolation features disposed on opposite sides of the fin-shaped active region may lead to fin cracking issues. Therefore, while existing methods of forming multi-gate devices (e.g., fin field-effect transistors (FinFETs), gate-all-around (GAA) transistors) may be generally adequate for their intended purposes, they are not satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1A is a diagrammatic plan view of an IC chip, in portion or entirety, according to various aspects of the present disclosure.

FIGS. 1B and 1C are diagrammatic plan views of an array of memory cells, such as static random-access memory (SRAM) cells, in portion or entirety, according to various aspects of the present disclosure.

FIG. 2 is a circuit diagram of a memory cell, such as an SRAM cell, that can be implemented in the IC chip of FIG. 1, according to various aspects of the present disclosure.

FIG. 3 is a fragmentary layout of an array of memory cells, according to various aspects of the present disclosure.

FIG. 4 illustrates a flowchart of an exemplary method for fabricating a semiconductor structure, according to various embodiments of the present disclosure.

FIGS. 5A, 6A, 7A, 8A, 9A, 10A, 11A, 12A, 13A, 14A, 15A, and 16A illustrate fragmentary top views of a structure during various fabrication stages in the method of FIG. 4, according to various aspects of the present disclosure.

FIGS. 5B, 6B, 7B, 8B, 9B, 10B, 11B, 12B, 13B, 14B, 15B, and 16B illustrate fragmentary cross-sectional views of the structure taken along line A-A during various fabrication stages in the method of FIG. 4, according to various aspects of the present disclosure.

FIGS. 12C, 13C, 14C, 15C, and 16C illustrate fragmentary cross-sectional views of the structure taken along line B-B during various fabrication stages in the method of FIG. 4, according to various aspects of the present disclosure.

FIG. 12D illustrates a simplified layout of the structure shown in FIG. 12A, according to various aspects of the present disclosure.

FIG. 16D illustrates a fragmentary cross-sectional view of the structure taken along line C-C shown in FIG. 16A, according to various aspects of the present disclosure.

FIG. 16E illustrates a simplified layout of the structure shown in FIG. 16A, according to various aspects of the present disclosure.

FIG. 17 illustrates a fragmentary cross-sectional view of a first alternative structure, according to various aspects of the present disclosure.

FIG. 18 illustrates a simplified layout of a second alternative, according to various aspects of the present disclosure.

FIG. 19 illustrates a simplified layout of a third alternative, according to various aspects of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

The present disclosure provides integrated circuit structures having fin-shaped active regions that are less prone to cracking issues. In an embodiment, when viewed from top, a fin-shaped active region has a uniform fin width and has a first portion including curved sidewalls and a second portion including substantially straight sidewalls. Thus, variations between isolation features formed adjacent to opposite sides of the first portion of the fin-shaped active region will be reduced, thereby improving device reliability.

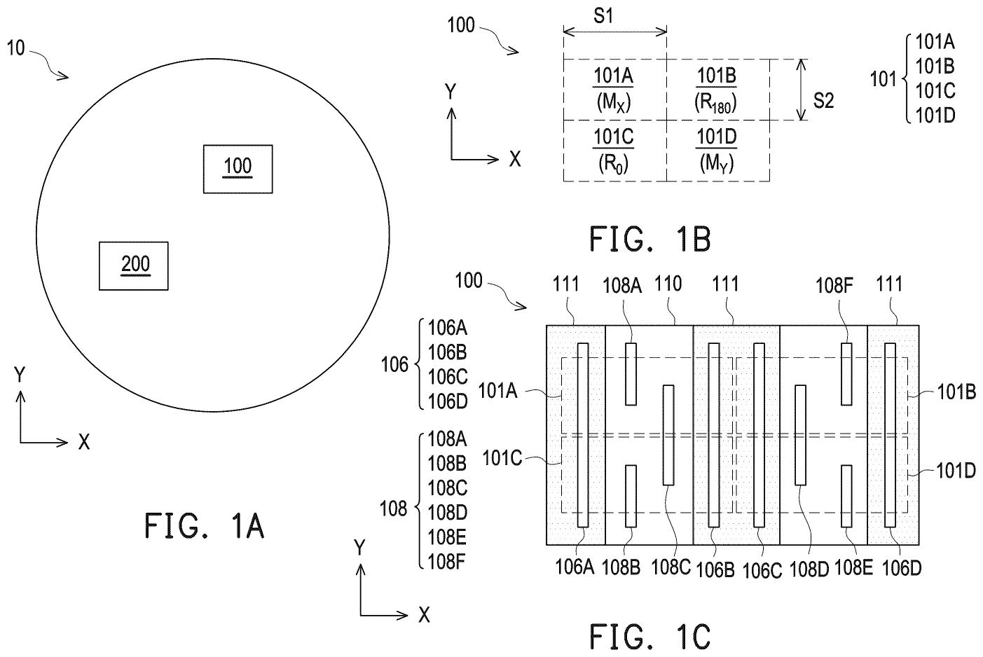

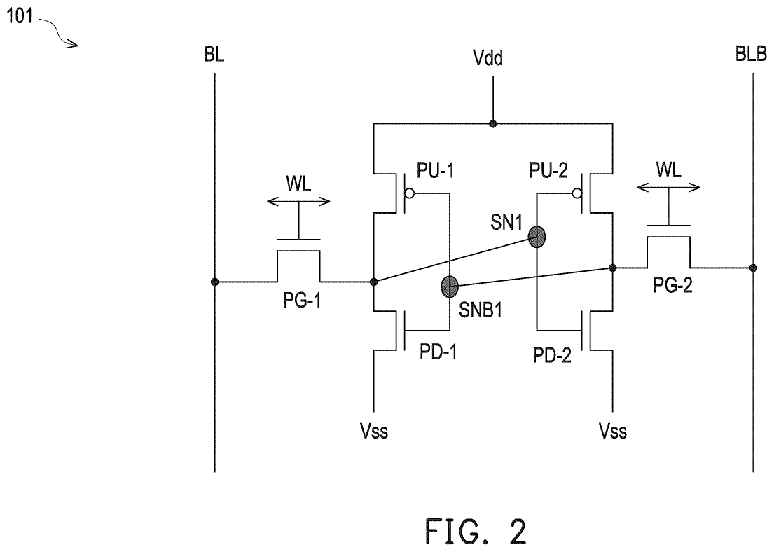

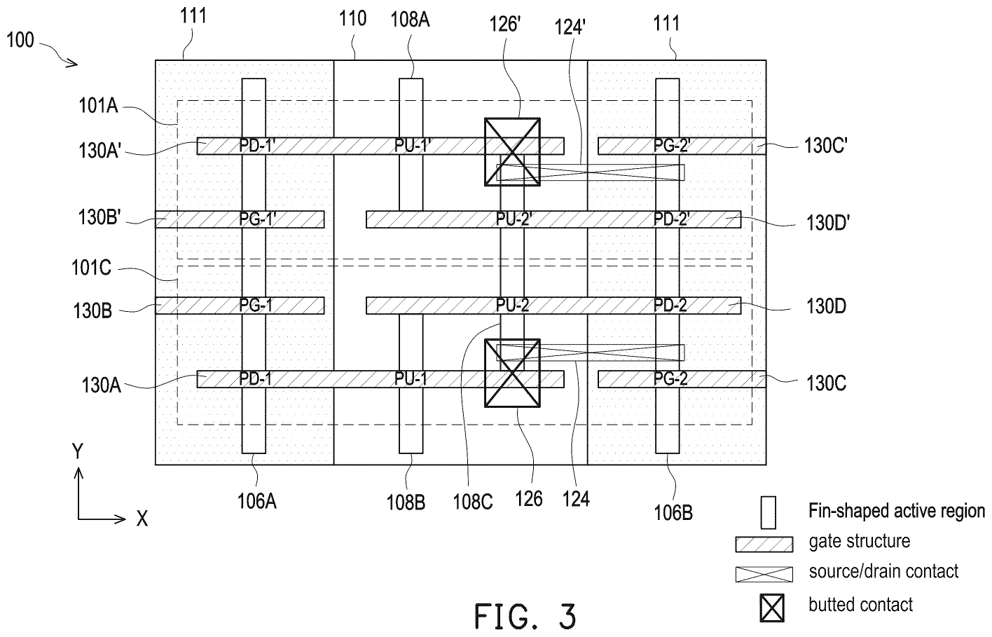

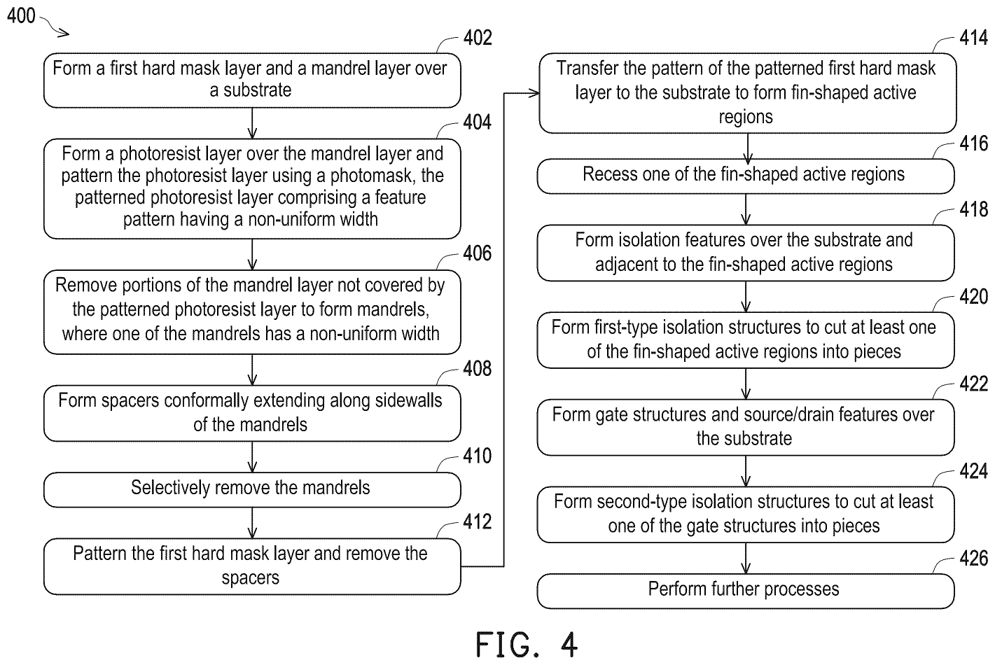

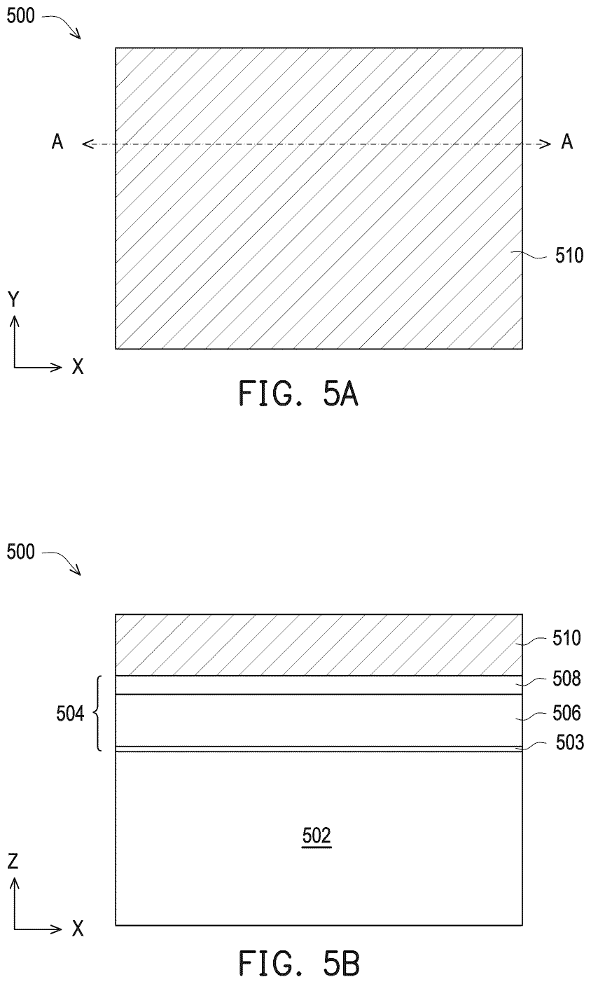

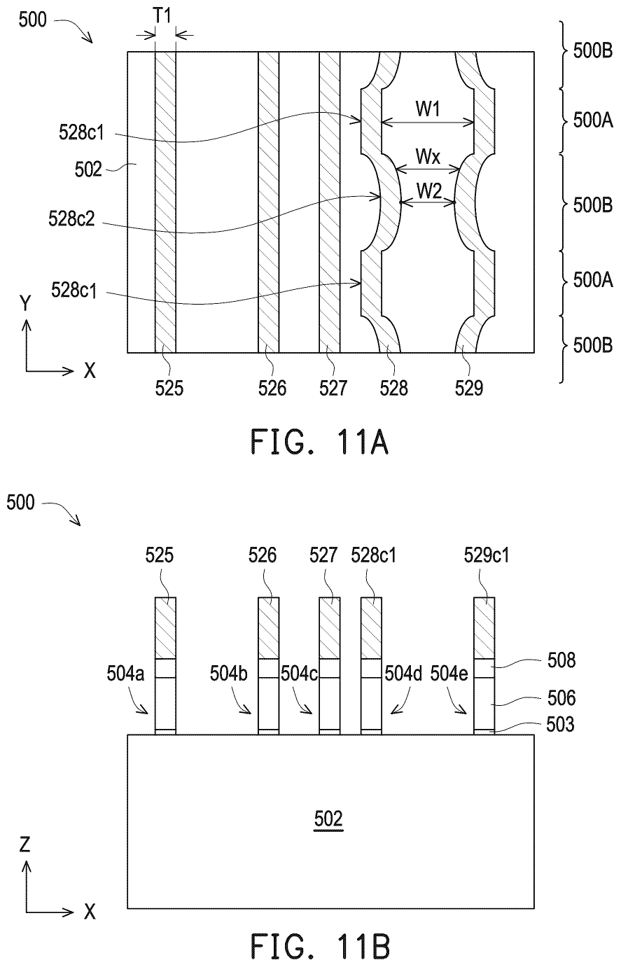

The various aspects of the present disclosure will now be described in more detail with reference to the figures. In that regard, FIG. 1A is a diagrammatic plan view of an exemplary IC chip. FIGS. 1B and 1C are diagrammatic plan views of an array of memory cells, such as static random-access memory (SRAM) cells, in portion or entirety, according to various aspects of the present disclosure. FIG. 2 is a circuit diagram of an SRAM cell that can be implemented in the IC chip of FIG. 1. FIG. 3 is a layout of a portion of an array (e.g., two SRAM cells), according to various aspects of the present disclosure. FIG. 4 is a flow chart illustrating method 400 of forming a semiconductor structure. Method 400 is described in conjunction with FIGS. 5A-19. Method 400 is merely an example and is not intended to limit the present disclosure to what is explicitly illustrated therein. Additional steps may be provided before, during, and/or after the method 400, and some steps described can be replaced, eliminated, or moved around for additional embodiments of the method. Not all steps are described herein in detail for reasons of simplicity. Because the structure 500 will be fabricated into an integrated circuit structure or semiconductor structure upon conclusion of the fabrication processes, the structure 500 may be referred to as the integrated circuit structure 500 or semiconductor structure 500 as the context requires. For avoidance of doubts, the X, Y and Z directions in FIGS. 1A-1C, 3, 5A-19 are perpendicular to one another and are used consistently throughout the present disclosure. Throughout the present disclosure, like reference numerals denote like features unless otherwise excepted.

Referring to FIG. 1A, the present disclosure provides an IC structure 10 including at least an array 100 of memory cells. The array 100 may include static random-access memory (SRAM) cells, dynamic random-access memory (DRAM) cells, non-volatile random-access memory (NVRAM) cells, flash memory cells, other suitable memory cells, or combinations thereof. The IC structure 10 may further include a number of other components, such as an array 200 of standard logic (STD) cells configured to provide various standard logic devices, such as inverter, AND, NAND, OR, XOR, NOR, other suitable devices, or combinations thereof. Additionally, the IC structure 10 may include various passive and active microelectronic devices, such as resistors, capacitors, inductors, diodes, bipolar transistors, high voltage transistors, high frequency transistors, other suitable devices, or combinations thereof. Additional features can be added to the IC structure 10 and some of the features described below can be replaced, modified, or eliminated in other embodiments of the IC structure 10.

In the present embodiments, referring to FIG. 1B, the array 100 includes a number of SRAM cells 101A, 101B, 101C, and 101D, which generally provide memory or storage capable of retaining data when power is applied. As such, the array 100 is hereafter referred to as SRAM array 100. In the present embodiments, each SRAM cell 101A-101D includes one or more transistors (e.g., FinFETs or GAA transistors) to be discussed in detail below. The SRAM cells 101A, 101B, 101C, and 101D, together defining a two-by-two grid, exhibit mirror and/or rotational symmetry with respect to each other. For example, using the SRAM cell 101C as a reference (denoted “R₀”), a layout of the SRAM cell 101A (denoted “M_{X}”) is a mirror image of a layout of the SRAM cell 101C with respect to the X-axis. Similarly, a layout of the SRAM cell 101B is a mirror image of the layout of the SRAM cell 101A, and a layout of the SRAM cell 101D (denoted “M_{Y}”) is a mirror image of the layout of the SRAM cell 101C, both with respect to the Y-axis. In other words, the layout of the SRAM cell 101B (denoted “R₁₈₀”) is symmetric to the layout of the SRAM 101C by a rotation of 180 degrees about a geometric center of the grid, which is defined as an intersection point of an imaginary line bisecting the rectangular grid along the Y-axis and an imaginary line bisecting the rectangular grid along the X-axis. Furthermore, in the depicted embodiments, the SRAM cells 101A-101D are substantially the same in size, i.e., having substantially the same horizontal (long) pitch S1 along the X-axis and a vertical (short) pitch S2 along the Y-axis. As such, the SRAM cells 101A-101D may hereafter be individually or collectively referred to as the SRAM cell 101 or SRAM cells 101, for purposes of simplicity.

Referring to FIG. 1C, a fragmentary layout view of active regions in the array 100 is illustrated. In this depicted example, three-dimensional fin-shaped active regions 106A, 106B, 106C, and 106D and three-dimensional fin-shaped active regions 108A, 108B, 108C, 108D, 108E and 108F are shown in FIG. IC. The three-dimensional fin-shaped active regions 106A, 106B, 106C, and 106D may hereafter be individually or collectively referred to as the fin 106 or fins 106, and the three-dimensional fin-shaped active regions 108A, 108B, 108C, 108D, 108E and 108F may hereafter be individually or collectively referred to as the fin 108 or fins 108. In an example, each SRAM cell 101 is configured to include p-type fins 106 each disposed in a p-type doped region 111 (hereafter referred to as p-well 111) and n-type fins 108 each disposed in a n-type doped region 110 (hereafter referred to as n-well 110), which is interposed between two p-wells 111. The p-type fins 106 and the n-type fins 108 are oriented lengthwise along Y direction and spaced from each other along X direction, which is substantially perpendicular to the Y direction. As will be discussed in detail below, each p-type fin 106 may be formed of a single-layer material having a uniform composition or may include a first set of vertically stacked semiconductor layers configured to provide channel regions of n-type FinFETs or GAA transistors, and each n-type fin 108 may be formed of a single-layer material having a uniform composition or a second set of vertically stacked semiconductor layers configured to provide channel regions of p-type FinFETs or GAA transistors. Various SRAM cells 101 may be configured for similar applications, such as a high-speed application, a low-power application, other suitable applications, or combinations thereof. Alternatively, different SRAM cells 101 may be configured for different applications and designed with different specifications (e.g., dimensions, layout designs, etc.) accordingly. Various aspects and embodiments of the array 100 and SRAM cell 101 are discussed in detail below. In this illustrated embodiment, the fin 108C extends along the Y direction and across the boundary between the SRAM cells 101A and 101C, and the fin 108D extends along the Y direction and across the boundary between the SRAM cells 101B and 101D. Each of the fins 108A, 108B, 108E and 108F extends along the Y direction and across a boundary of the SRAM cells 101A, 101C, 101D and 101B, respectively. Each of the fins 106 extends along the Y direction and extends across two SRAM cells.

FIG. 2 illustrates an exemplary circuit schematic for a single-port SRAM cell (e.g., 1-bit SRAM cell) 101. The single-port SRAM cell 101 includes pull-up transistors PU-1, PU-2; pull-down transistors PD-1, PD-2; and pass-gate transistors PG-1, PG-2. As show in the circuit diagram, transistors PU-1 and PU-2 are p-type transistors, and transistors PG-1, PG-2, PD-1, and PD-2 are n-type transistors. Since the SRAM cell 101 includes six transistors in the illustrated embodiment, it may also be referred to as a 6T SRAM cell.

The drains of pull-up transistor PU-1 and pull-down transistor PD-1 are coupled together, and the drains of pull-up transistor PU-2 and pull-down transistor PD-2 are coupled together. Transistors PU-1 and PD-1 are cross-coupled with transistors PU-2 and PD-2. The gates of transistors PU-2 and PD-2 are coupled together and to the drains of transistors PU-1 and PD-1 to form a storage node SN1, and the gates of transistors PU-1 and PD-1 are coupled together and to the drains of transistors PU-2 and PD-2 to form a complementary storage node SNB1. Sources of the pull-up transistors PU-1 and PU-2 are coupled to power voltage Vdd, and the sources of the pull-down transistors PD-1 and PD-2 are coupled to a voltage Vss, which may be an electrical ground in some embodiments. The storage node SN1 is coupled to bit line BL through pass-gate transistor PG-1, and the complementary storage node SNB1 is coupled to complementary bit line BLB through pass-gate transistor PG-2. The storage node SN1 and the complementary storage node SNB1 are complementary nodes that are often at opposite logic levels (logic high or logic low). Gates of pass-gate transistors PG-1 and PG-2 are coupled to a word line WL.

FIG. 3 is a fragmentary layout of a portion of the array 100, according to various aspects of the present disclosure. Additional features can be added to the layout and some of the features described below can be replaced, modified, or eliminated in other embodiments. In the depicted embodiments, the n-well 110 is disposed between two p-wells 111. The n-well 110 is configured to provide at least one p-type field-effect transistor (PFET), such as a pull-up transistor, and each p-well 111 is configured to provide at least one n-type field-effect transistor (NFET), such as a pull-down transistor or a pass-gate transistor. In the present embodiments represented in FIG. 3A, each SRAM cell 101 includes two p-type fins 106 each disposed in a p-well 111 and two n-type fins 108 disposed in an n-well 110 interposing between the two p-wells 111.

In the depicted embodiments, for the SRAM cell 101C, portions of a gate structure 130A engage with the p-type fin 106A and n-type fin 108B to form a pull-down transistor PD-1 and a pull-up transistor PU-1, respectively; a portion of a gate structure 130B engages with the p-type fin 106A to form a pass-gate transistor PG-1; a portion of a gate structure 130C engages with the p-type fin 106B to form a pass-gate transistor PG-2; and portions of a gate structure 130D engage with the p-type fin 106B and the n-type fin 108C to form a pull-down transistor PD-2 and a pull-up transistor PU-2, respectively. A layout of the SRAM cell 101A (denoted “M_{X}”) is a mirror image of a layout of the SRAM cell 101C with respect to the X-axis. More specifically, for the SRAM cell 101A, portions of a gate structure 130A′ engage with the p-type fin 106A and n-type fin 108A to form a pull-down transistor PD-1′ and a pull-up transistor PU-1′, respectively; a portion of a gate structure 130B′ engages with the p-type fin 106A to form a pass-gate transistor PG-1′; a portion of a gate structure 130C′ engages with the p-type fin 106B to form a pass-gate transistor PG-2′; and portions of a gate structure 130D′ engage with the p-type fin 106B and the n-type fin 108C to form a pull-down transistor PD-2′ and a pull-up transistor PU-2′, respectively. In some embodiments, the pull-down transistors are configured as p-type transistors, while the pull-up transistors and pass-gate transistors are configured as n-type transistors. Drain of the PD-2 and drain of the PU-2 are electrically connected by a source/drain contact 124. Gate structure 130A of the PU-1 is electrically connected to drain of the PU-2 by a butted contact 126 or by other means. Drain of the PD-2′ and drain of the PU-2′ are electrically connected by a source/drain contact 124′. Gate structure 130A′ of the PU-1′ is electrically connected to drain of the PU-2′ by a butted contact 126′ or by other means. Some features (e.g., source/drain contacts, gate vias) are omitted in this layout for reason of simplicity.

In some technologies, after forming the fins (e.g., fins 106 and 108), isolation features such as shallow trench isolation (STI) features are formed to provide isolation between two adjacent fins. In an exemplary process, a dielectric material for the isolation features is deposited over a substrate using chemical vapor deposition (CVD), sub-atmospheric CVD (SACVD), flowable CVD (FCVD), physical vapor deposition (PVD), spin-on coating, and/or other suitable process. Then the deposited dielectric material is annealed, planarized, and recessed until the fins (e.g., fins 106 and 108) rise above the isolation features. The formation of the isolation features may involve one or more processes (e.g., annealing, FCVD) conducted at elevated temperature. When an isolation feature formed adjacent to one side of a fin has different configurations (e.g., different depths) than an isolation feature formed adjacent to another side of the fin, the fabrication process of the isolation features may exert stress on the fin, causing cracking of the fin and leading to device failure.

Method for reducing possibility of cracking of the fin is described below with reference to FIGS. 4-19. Referring now to FIGS. 4 and 5A-5B, method 400 includes a block 402 where a structure 500 including a first hard mask layer 504 and a mandrel layer 510 over a substrate 502 is received. FIG. 5A depicts a fragmentary top view of the structure 500, and FIG. 5B depicts a fragmentary cross-sectional view of the structure 500. In the present embodiments, the substrate 502 includes silicon. Alternatively, or additionally, the substrate 502 includes another elementary semiconductor, such as germanium; a compound semiconductor, such as silicon carbide, silicon phosphide, gallium arsenide, gallium phosphide, indium phosphide, indium arsenide, and/or indium antimonide; an alloy semiconductor, such as SiGe, SiPC, GaAsP, AlInAs, AlGaAs, GaInAs, GaInP, and/or GaInAsP; or combinations thereof. In some embodiments, the substrate 502 is a semiconductor-on-insulator substrate, such as a silicon-on-insulator (SOI) substrate, a silicon germanium-on-insulator (SGOI) substrate, or a germanium-on-insulator (GOI) substrate. Semiconductor-on-insulator substrates can be fabricated using separation by implantation of oxygen (SIMOX), wafer bonding, other suitable methods, or combinations thereof. The substrate 502 includes the n-wells 110 (not separately labeled) and the p-wells 111 (not separately labeled). Each n-well 110 may be doped with an n-type dopant, such as phosphorus, arsenic, other n-type dopants, or combinations thereof. Each p-well 111 may be doped with a p-type dopant, such as boron, indium, other p-type dopants, or combinations thereof.

The first hard mask layer 504 may be a single layer or a multi-layer. In some embodiments represented in FIG. 5B, the first hard mask layer 504 is a multi-layer that includes a first layer 506 and a second layer 508 over the first layer 506. The first layer 506 may be formed of silicon nitride, silicon oxynitride, silicon carbonitride, or other suitable dielectric material, and the second layer 508 may be formed of silicon oxide or other suitable dielectric material. In one embodiment, the first layer 506 is formed of silicon nitride and the second layer 508 is formed of silicon oxide. The first hard mask layer 504 may be deposited using chemical vapor deposition (CVD), atomic layer deposition (ALD), or other suitable deposition technique. In some implementations shown in FIG. 5B, a pad oxide layer 503 may be formed over the substrate 502 before the deposition of the first hard mask layer 504 to improve adhesion. The pad oxide layer 503 may be formed by thermal oxidation, ALD, CVD, or a suitable method. A mandrel layer 510 (or a “sacrificial layer 510”) is then deposited over the first hard mask layer 504. In one embodiment, the mandrel layer 510 may be a silicon nitride or a polysilicon layer deposited using CVD, low pressure CVD (LPCVD), ALD.

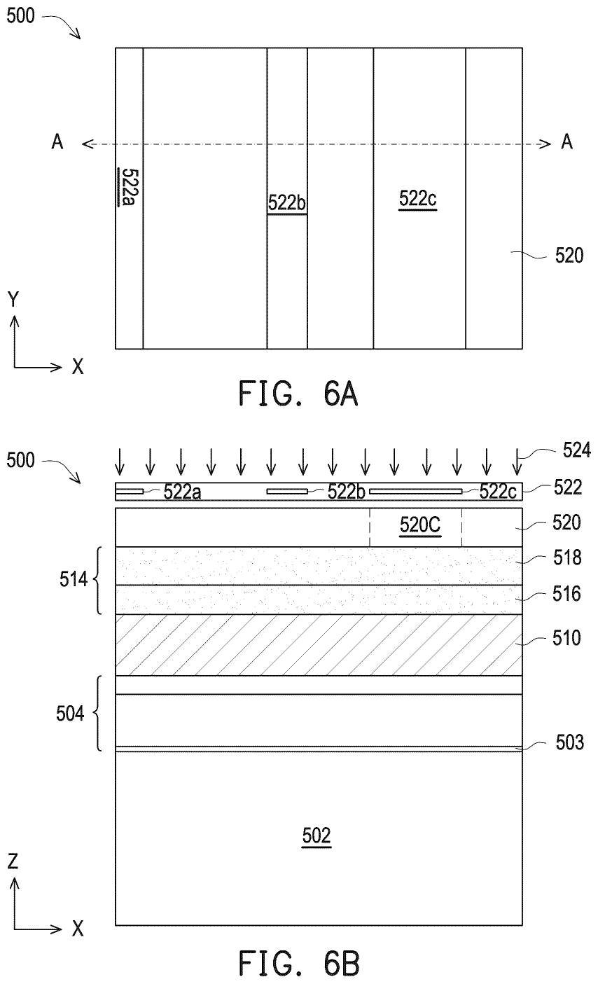

Referring now to FIGS. 4, 6A-6B and 7A-7B, method 400 includes a block 404 where a photoresist layer 520 is formed over the mandrel layer 510 and patterned. With respect to FIGS. 6A-6B, in some embodiments, before forming the photoresist layer 520, a second hard mask layer 514 may be formed on the mandrel layer 510. The second hard mask layer 514 may be similar to the first hard mask layer 504 and may include a first layer 516 and a second layer 518 over the first layer 516. The photoresist layer 520 is then deposited over the second hard mask layer 514 using spin-on coating, CVD, or other similar processes. In some embodiments, the photoresist layer 520 includes a bottom layer (not shown), a middle layer (not shown), and an upper layer (not shown). The bottom layer and upper layer may be formed of photosensitive materials, such as organic materials, while the middle layer may comprise an inorganic material, such as nitride, oxynitride, oxide, or the like. In an embodiment, the bottom layer is a bottom anti-reflective coating (BARC) layer. In some embodiments, the photoresist layer 520 is a monolayer or bilayer structure in which at least one layer (such as the middle layer) is omitted from the photoresist layer 520.

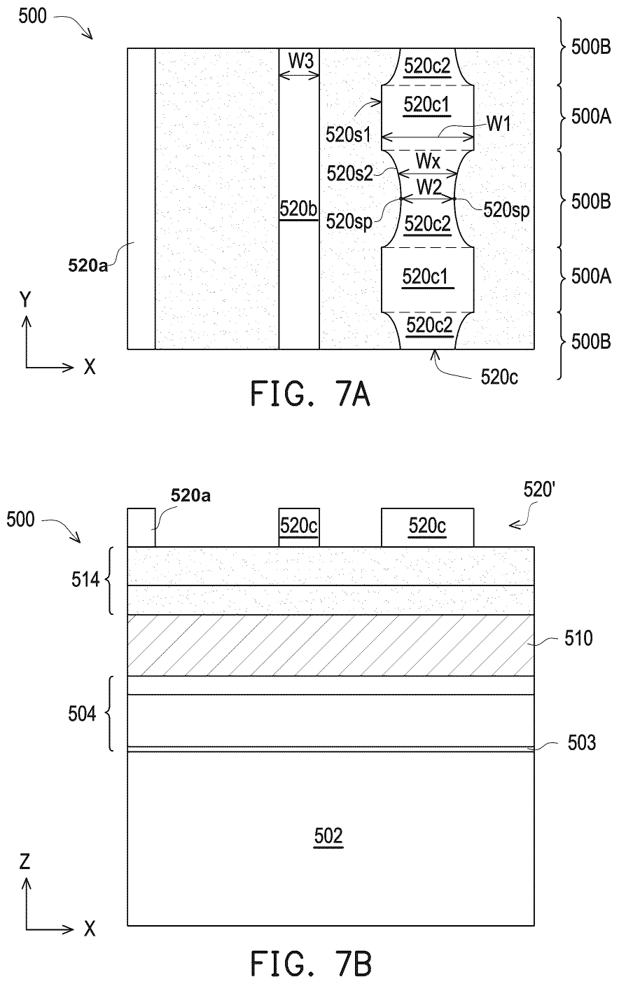

The photoresist layer 520 is baked in a pre-exposure baking process. The pre-baked photoresist layer is then exposed to a radiation source 524 reflected from or transmitting through a photomask 522 with pattern. In this illustrated embodiment, the photomask 522 includes a pattern feature 522a, a pattern feature 522b, and a pattern feature 522c. Each of the pattern feature 522a-522c has a corresponding uniform width and substantially straight sidewalls (see FIG. 6A). When viewed from top, each of the pattern feature 522a-522c may resemble a rectangle. In an embodiment, a width of the pattern feature 522c is greater than a width of the pattern feature 522b. The radiation source may be an excimer laser light source, an ultraviolet (UV) source, a deep UV (DUV) source, or an extreme UV (EUV) source. The exposed photoresist layer 520 is then baked in a post-exposure baking process and developed in a developing process. Because the photoresist layer 520 is selected to be sensitive to the radiation, exposed (or non-exposed) portions of the photoresist layer 520 undergo chemical changes to become soluble in a developer solution during a subsequent developing process. In this embodiment, parameters of the photolithography process is adjusted such that a portion 520c of the photoresist layer 520 disposed directly under the pattern feature 522c are non-uniformly exposed. That is, the radiation source 524 does not uniformly change the chemical property of the portion 520c of the photoresist layer 520. In some embodiments, rule based optical proximity correction (OPC) technique is implemented to facilitate the formation of the non-uniformly exposed portion 520c. For example, the exposed portion 520c of the photoresist layer 520 may be aggressively reshaped by OPC on some desired parts. The actual exposed portion 520c will be described in more detail with reference to FIGS. 7A-7B. The exposed photoresist layer 520 is then baked in a post-exposure baking process and developed in a developing process, thereby forming a patterned photoresist layer 520′.

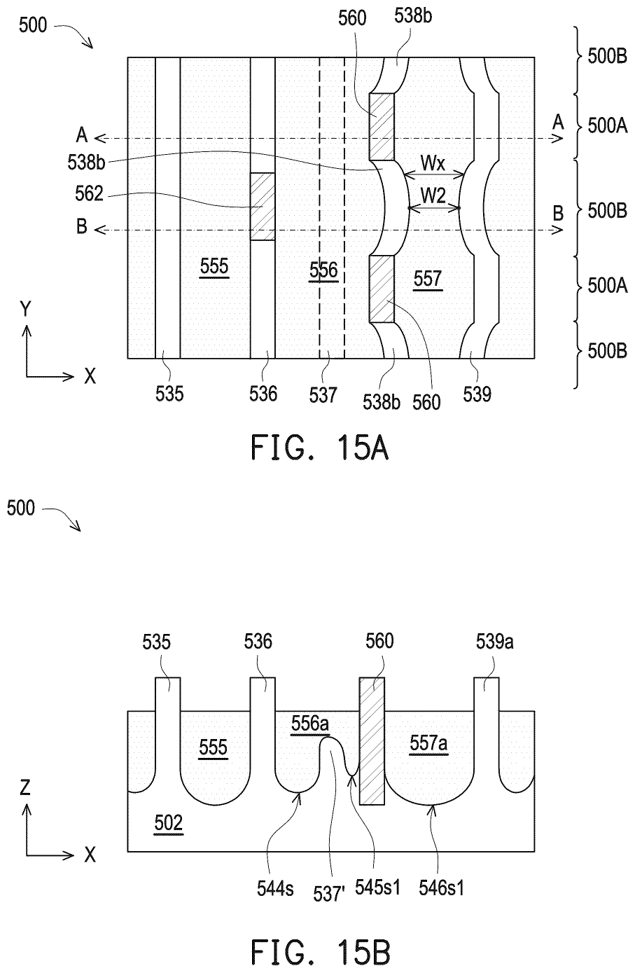

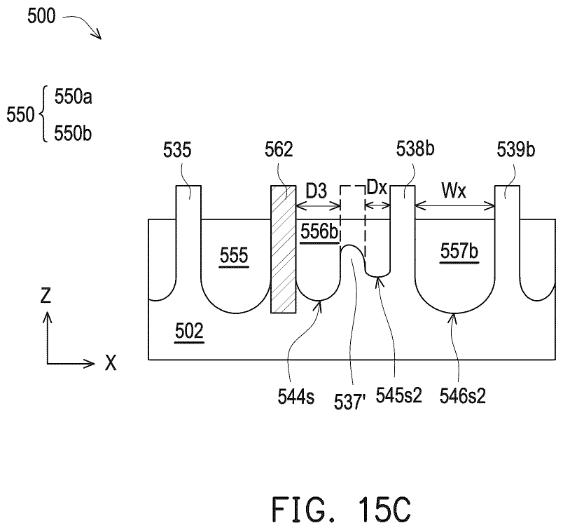

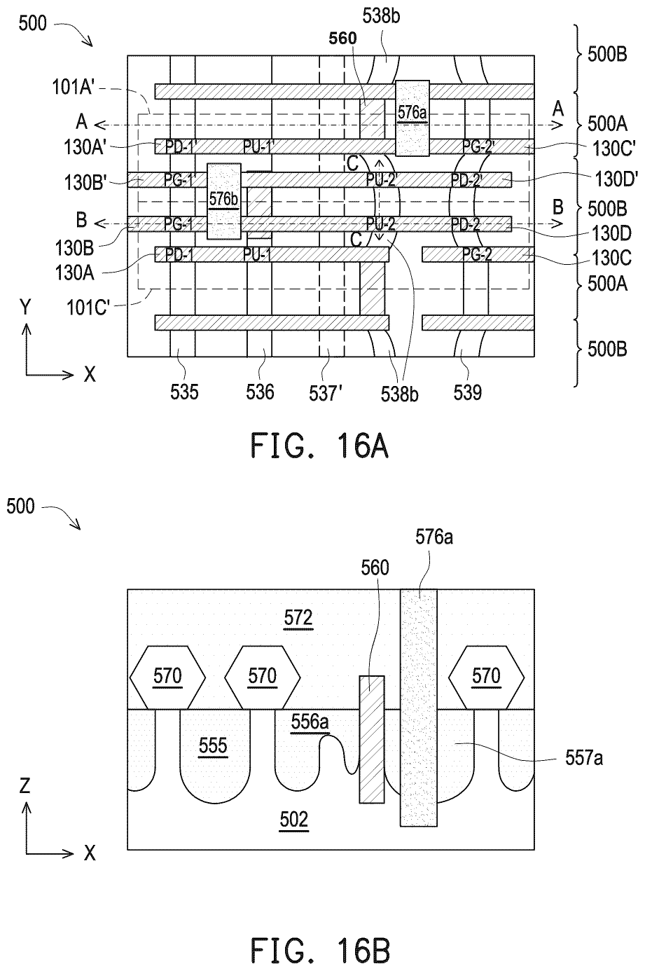

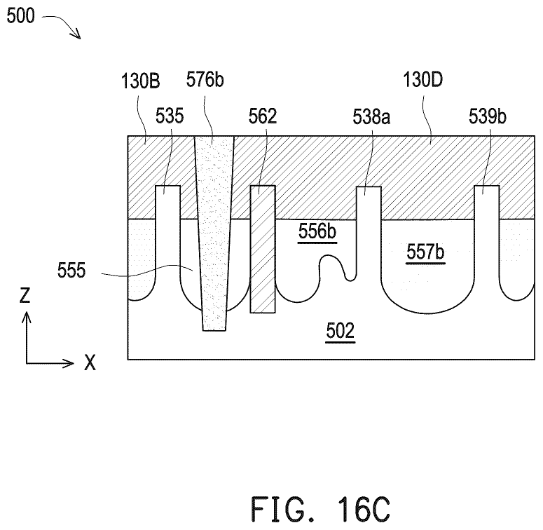

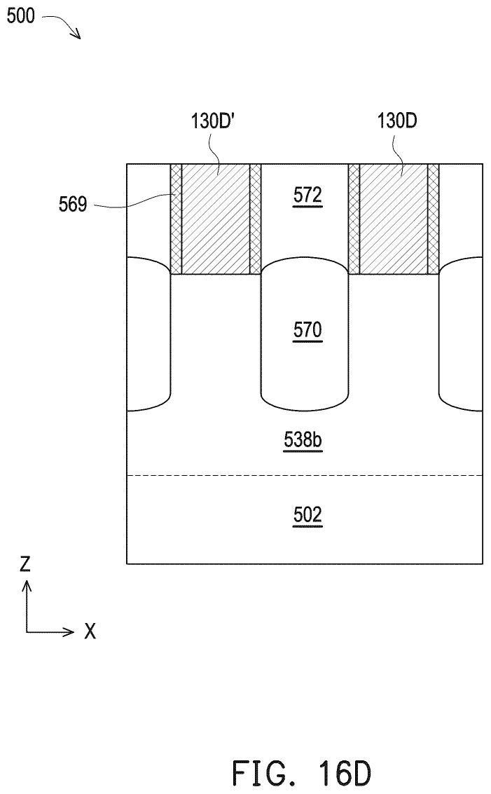

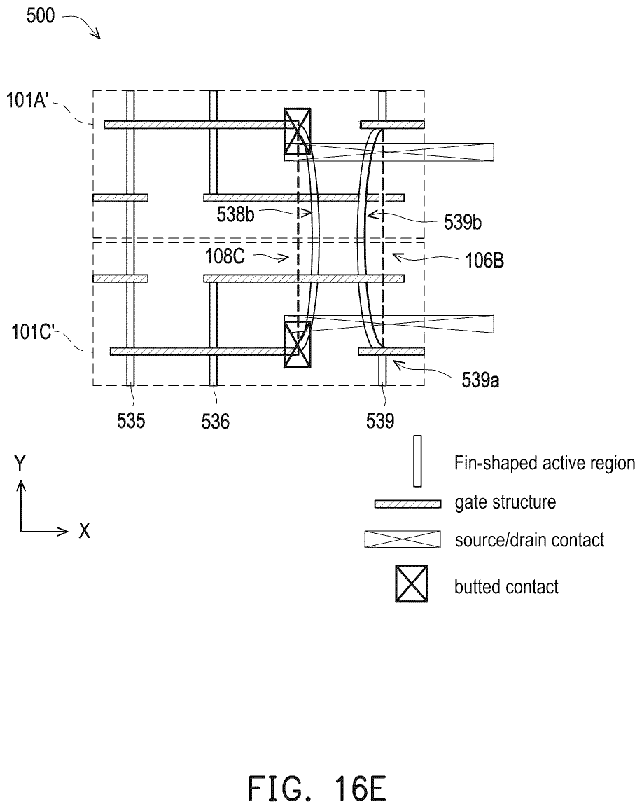

With respect to FIGS. 7A-7B, the patterned photoresist layer 520′ carries pattern that corresponds to the pattern of the photomask 522, except that the portion 520c of the patterned photoresist layer 520′ is different than the corresponded pattern feature 522c. In this illustrated embodiment, when viewed from top, as represented by FIG. 7A, a portion 520a of the patterned photoresist layer 520′ corresponds to the pattern feature 522a and has substantially straight sidewalls and a substantially uniform width, a portion 520b of the patterned photoresist layer 520′ corresponds to the pattern feature 522b and has substantially straight sidewalls and a substantially uniform width W3, while the portion 520c has a profile different than the pattern feature 522c and has a non-uniform width. More specifically, the portion 520c includes a part 520c1 formed over a first region 500A of the structure 500 and a part 520c2 formed over a second region 500B of the structure 500. The part 520c1 has a uniform width W1 and substantially straight sidewalls 520s1. In an embodiment, the part 520c1 resembles a rectangle. The part 520c2 has a non-uniform width Wx less than the width W1. The part 520c2 has curved sidewalls 520s2 and may curve inward the most at the middle point 520sp of the corresponding sidewall 520s2. The narrowest portion of the part 520c2 has a width W2 measured between middle points 520sp of two sidewall 520s2. Width W2 is less than width W1. In this illustrated example, the part 520c2 resembles a concave lens or a diverging lens. Along the Y direction, the width Wx of the part 520c2 gradually decreases from width W1 to width W2 and then gradually increases from width W2 to width W1, and W1>Wx≥W2. In an embodiment, the width W2 and the width WI are greater than the width W3. The structure 500 may include multiple first regions 500A and multiple second regions 500B. Each of the second regions 500B is disposed between two first regions 500A. The number of the first regions 500A and second regions 500B depicted in FIG. 7A is just an example. Differences between the first region 500A and second region 500B will be described in detail with reference to FIGS. 15A and 16A.

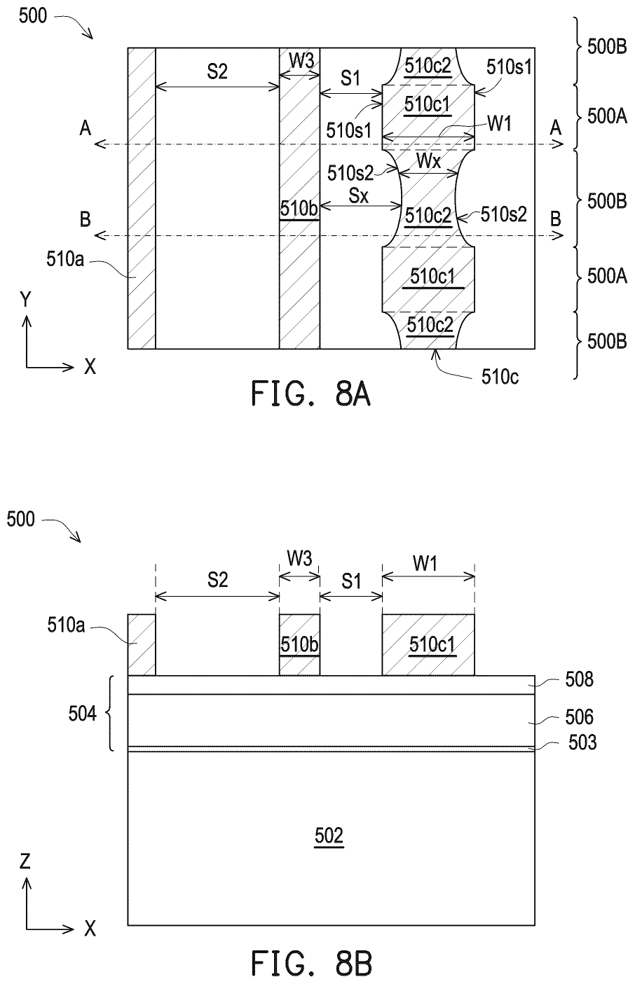

Referring now to FIGS. 4 and 8A-8B, method 400 includes a block 406 where portions of the mandrel layer 510 not covered by the patterned photoresist layer 520′ are removed to form mandrels (e.g., mandrels 510a, 510b, 510c). FIG. 8A depicts a fragmentary top view of the structure 500, and FIG. 8B depicts a fragmentary cross-sectional view of the structure 500 taken along line A-A shown in FIG. 8A. In this depicted example, after forming the patterned photoresist layer 520′, a first etching process is performed to transfer the pattern of the patterned photoresist layer 520′ to the second hard mask layer 514 disposed thereunder. That is, after the first etching process, when viewed from top, a portion of the second hard mask layer 514 disposed directly under the portion 520c of the patterned photoresist layer 520′ has a profile substantially similar to the profile of the portion 520c of the patterned photoresist layer 520′. The first etching process can include a dry etching process (for example, a reactive ion etching (RIE) process), a wet etching process, other suitable etching process, or combinations thereof. After the first etching process, the patterned photoresist layer 520 can be removed by ashing or a suitable method. After forming the patterned second hard mask layer 514, a second etching process is performed to transfer the pattern of the patterned second hard mask layer 514 to the mandrel layer 510 disposed thereunder. The second etching process can include a dry etching process (for example, a reactive ion etching (RIE) process), a wet etching process, other suitable etching process, or combinations thereof. After the second etching process, the patterned second hard mask layer 514 may be selectively removed.

In this illustrated embodiment, the patterned mandrel layer 510 includes a mandrel 510a, a mandrel 510b, and a mandrel 510c. When viewed from top, the profile of the mandrel 510a is substantially the same as the profile of the portion 520a of the patterned photoresist layer 520′, the profile of the mandrel 510b is substantially the same as the profile of the portion 520b of the patterned photoresist layer 520′, and the profile of the mandrel 510c is substantially the same as the profile of the portion 520c of the patterned photoresist layer 520′. That is, when viewed from top, as represented by FIG. 8A, the mandrel 510c has a first part 510c 1 formed over the first region 500A of the structure 500 and having substantially straight sidewalls 510s1 and the substantially uniform width W1. The mandrel 510c also has a second part 510c2 formed over the second region 500B of the structure 500 and having the non-uniform width Wx less than the width W1. The part 510c2 has curved sidewalls 510s2 and may curve inward the most at the middle point of the sidewall 510s2. In this illustrated example, the second part 510c2 resembles a concave lens or a diverging lens.

The first part 510c1 of the mandrel 510c is spaced apart from the mandrel 510b by a spacing S1. The second part 510c2 of the mandrel 510c is spaced apart from the mandrel 510b by a spacing Sx greater than the spacing S1. The spacing S1 is a fixed number, and the spacing Sx is varying (i.e., non-uniform) depending on the width Wx of the second part 510c2. In an embodiment, the mandrel 510b is spaced apart from the mandrel 510a by a spacing S2 that is greater than both the spacing S1 and the spacing Sx. A cross-sectional view of the structure 500 taken along line B-B shown in FIG. 8A is similar to the cross-sectional view represented by FIG. 8B, except for the width Wx of the second part 510c2 and the spacing Sx between the mandrel 510b and the second part 510c2. A cross-sectional view of the structure 500 taken along line B-B shown in FIG. 8A is thus omitted for reason of simplicity.

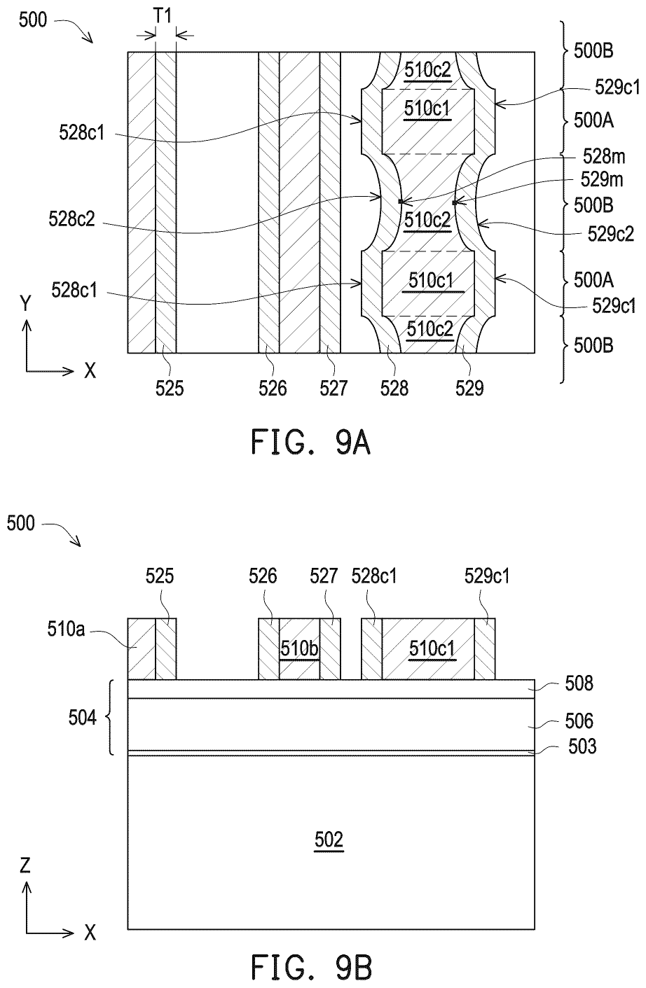

Referring now to FIGS. 4 and 9A-9B, method 400 includes a block 408 where spacers (e.g., spacers 525-529) are formed to conformably extending along sidewalls of the mandrels (e.g., the mandrels 510a-510c). In an example process, a spacer layer (not shown) is blanketly deposited over the structure 500, including over the mandrels 510a-510c. In an embodiment, the spacer layer is conformally deposited to have a generally uniform thickness T1 over the structure 500, including on the top surfaces and along sidewalls of the mandrels 510a-510c. The spacer layer may be formed of a material that has an etching selectivity different from that of the mandrels 510a-510c such that the mandrels 510a-510c may be selectively removed at a subsequent process. For example, the spacer layer may be formed of silicon nitride, silicon oxynitride, silicon carbonitride, silicon carbide, or other suitable materials. The spacer layer is then etched back to expose top surfaces of the mandrels 510a-510c. The etch back of the spacer layer leaves behind vertical portions of the spacer layer that extend along sidewalls of the mandrels 510a-510c while horizontal portions of the spacer layer that cover the top surfaces of the mandrels 510a-510c are removed, thereby forming the spacers 525, 526, 527, 528, and 529 each having a corresponding uniform width (along the X direction) that is substantially equal to the deposition thickness T1. In this illustrated embodiment, the spacer 525 extends along a sidewall of the mandrel 510a, the spacer 526 and the spacer 527 extend along two opposite sidewalls of the mandrel 510b, respectively, and the spacer 528 and the spacer 529 extend along two opposite sidewall of the mandrel 510c, respectively. Each of the spacers 525-529 tracks the shape of the corresponding sidewall of the corresponding mandrel. In other words, when viewed from top, each of the spacers 525-527 has substantially straight sidewalls, the spacer 528 has a portion 528c1 having substantially straight sidewalls and a portion 528c2 having curved sidewalls curved towards the second part 510c2 of the mandrel 510c, and the spacer 529 has a first portion 529c1 having substantially straight sidewalls and a second portion 529c2 having curved sidewalls curved towards the second part 510c2 of the mandrel 510c. The portion 528c2 curves the most at the middle points 528m of its sidewalls, and the second portion 529c2 curves the most at the middle points 529m of its sidewalls. The spacer 528 is spaced apart from the spacer 529 by the mandrel 510c. That is, the distance between the spacer 528 and the spacer 529 is non-uniform and is substantially equal to the width (W1 or Wx) of the mandrel 510c. Repeated description about the distance between the spacer 528 and the spacer 529 is thus omitted for reason of simplicity. Since the spacer 528 has a uniform width and have sidewalls curved towards the spacer 529, the distance between the spacer 527 and the spacer 528 is non-uniform. More specifically, a distance between the spacer 527 and the portion 528c1 of the spacer 528 is fixed, and a distance between the spacer 527 and the portion 528c2 of the spacer 528 is varying. In this embodiment, there is a negative relationship between the width Wx and the distance between the spacer 527 and the portion 528c2 of the spacer 528.

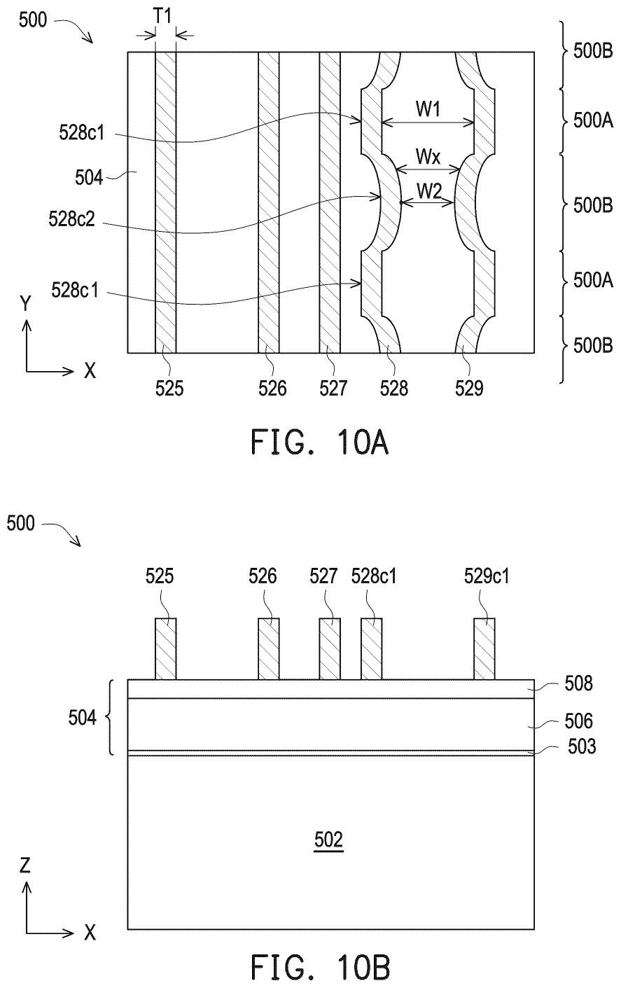

Referring now to FIGS. 4 and 10A-10B, method 400 includes a block 410 where the mandrels 510a-510c are selectively removed. After forming the spacers 525-529, an etching process is performed to selectively remove the mandrels 510a-510c without substantially etching the spacers 525-529. The etching process may be a dry etch, wet etch, or a combination thereof.

Referring now to FIGS. 4, 11A-11B and 12A-12C, method 400 includes a block 412 where the first hard mask layer 504 is patterned and the spacers 525-529 are selectively removed. In this embodiment, the first hard mask layer 504 is patterned using the spacers (e.g., the spacers 525-529) as an etch mask. After patterning the first hard mask layer 504, another etching process may then be performed to remove portions of the pad oxide layer 503 not covered by the first hard mask layer 504. Upon conclusion of operations at block 412, the first hard mask layer 504 and the pad oxide layer 503 are patterned to form mask features 504a, 504b, 504c, 504d, and 504c, respectively.

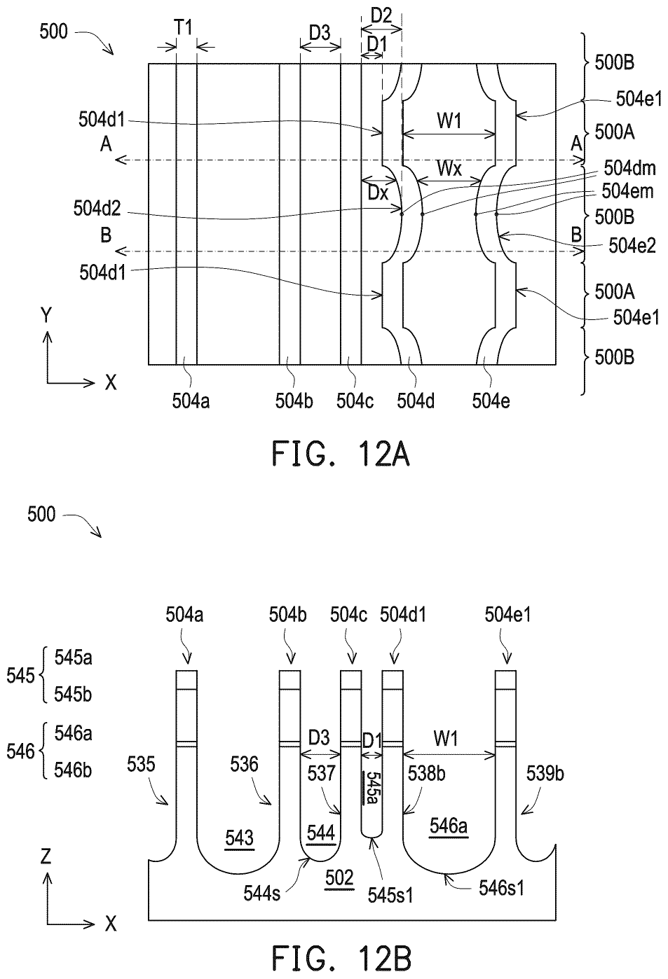

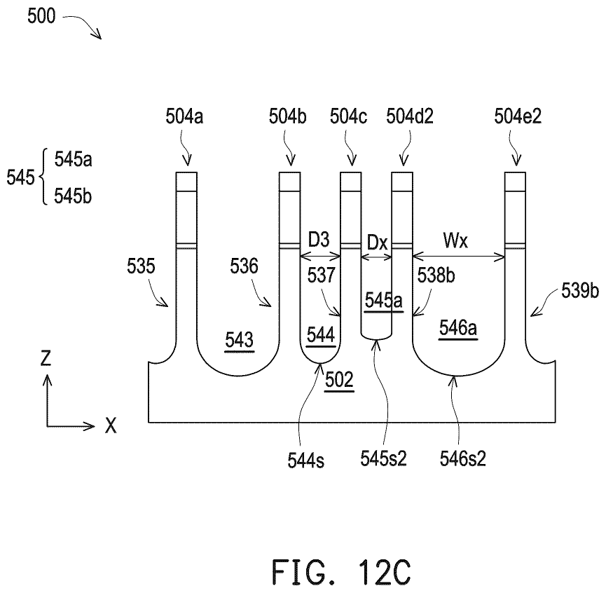

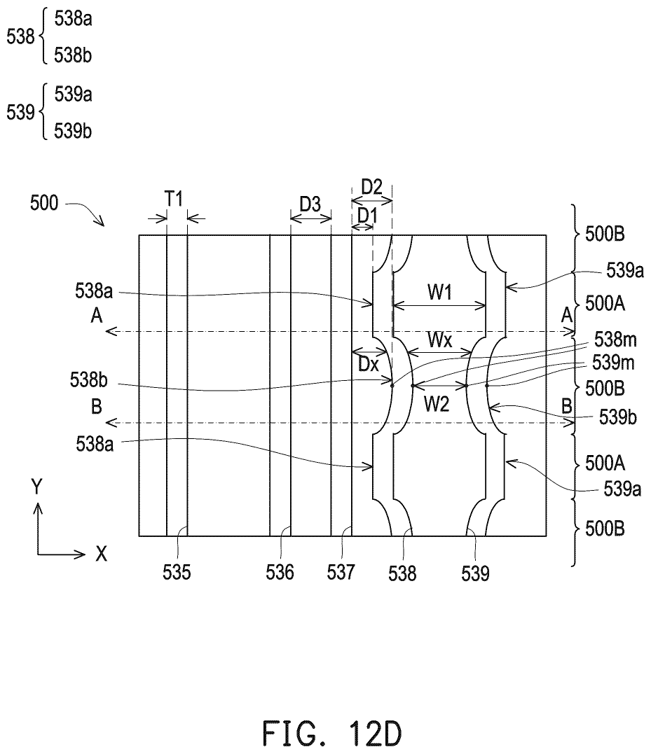

As illustrated in FIGS. 12A-12C, after forming the mask features 504a, 504b, 504c, 504d, and 504c, the spacers 525-529 are selectively removed. When viewed from top, the mask features 504a, 504b, 504c, 504d, and 504c track the profile of the corresponding spacers 525-529, respectively. In other words, when viewed from top, each of the mask features 504a, 504b, 504c has substantially straight sidewalls, the mask feature 504d has a first portion 504d1 having substantially straight sidewalls and a second portion 504d2 having curved sidewalls curved towards the mask feature 504e, and the mask feature 504e has a first portion 504e1 having substantially straight sidewalls and a second portion 504e2 having curved sidewalls curved towards the mask feature 504d. The second portion 504d2 curves the most at the middle points 504dm of its sidewalls (inner sidewall and outer sidewall), and the second portion 504e2 curves the most at the middle points 504em of its sidewalls (inner sidewall and outer sidewall). The distance between the mask feature 504e and the mask feature 504d is non-uniform and is substantially equal to the width of the mandrel 510c. Repeated description about the distance between the mask feature 504e and the mask feature 504d is thus omitted for reason of simplicity. Since the mask feature 504d has a uniform width and have sidewalls curved towards the mask feature 504e, the distance between the mask feature 504c and the mask feature 504d is non-uniform. More specifically, a distance DI between the mask feature 504c and the first portion 504d1 of the mask feature 504d is fixed, and a distance Dx between the mask feature 504c and the second portion 504d2 of the mask feature 504d is varying. In this embodiment, there is a negative relationship between the distance Dx and the width Wx. The width Wx is in a range between the width W2 and the width W1, and the distance Dx is in a range between about D1 and distance D2, where D2 corresponds to the distance between the mask feature 504c and the middle point 504dm of the outer sidewall of the mask feature 504d that is closer to the mask feature 504c. A sum of the distance Dx and the width Wx is equal to a sum of the distance D1 and the width D1, which is equal to a sum of the distance D2 and the width W2. In this embodiment, when viewed from top, a distance D3 between the mask feature 504b and the mask feature 504c is fixed (e.g., uniform).

Referring now to FIGS. 4 and 12A-12D, method 400 includes a block 414 where fin-shaped active regions (or “fins”) are formed. FIG. 12B depicts a fragmentary cross-sectional view of the structure 500 taken along line A-A shown in FIG. 12A, FIG. 12C depicts a fragmentary cross-sectional view of the structure 500 taken along line B-B shown in FIG. 12A, and FIG. 12D depicts a fragmentary top view of fins of the structure 500.

In this illustrated embodiment, the substrate 502 is patterned using the patterned first hard mask layer 504 (including the mask features 504a-504c) as an etch mask. The substrate 502 may be anisotropically etched through the patterned first hard mask layer 504, thereby forming fins (e.g., fins 535, 536, 537, 538, 539) protruding from the substrate 502 and trenches (e.g., trenches 543, 544, 545, 546) disposed between the fins. The fins 535-539 are disposed directly under the mask features 504a-504e, respectively. As a result, when viewed from top (shown in FIG. 12D), each of the fins 535-539 tracks the profile of the corresponding mask feature thereon and has a corresponding uniform width (e.g., T1). In other words, as represented by FIG. 12D, each of the fins 535, 536, 537 has substantially straight sidewalls, the fin 538 has a first portion 538a having substantially straight sidewalls and a second portion 538b (or “fin 538b”) having sidewalls curved towards the fin 539, and the fin 539 has a first portion 539a having substantially straight sidewalls and a second portion 539b having sidewalls curved towards the fin 538. The portion 538b curves the most at the middle points 538m of its sidewalls (inner sidewall and outer sidewall), and the second portion 539b curves the most at the middle point 539m of its sidewall (inner sidewall and outer sidewall). The distance between the fin 538 and the fin 539 is non-uniform and is substantially equal to the width (W1 or Wx) of the mandrel 510c. Repeated description about the distance between the fin 538 and the fin 539 is thus omitted for reason of simplicity. Since the fin 538 has a uniform width and have curved sidewalls, the distance between the fin 537 and the fin 538 is non-uniform and is substantially equal to the distance between the mask feature 504c and the mask feature 504d, and repeated description is thus omitted for reason of simplicity.

In an embodiment, with reference to FIGS. 12B-12D, the width W1 is greater than the width Wx and the distance D3, the distance D3 is greater than the distance Dx, and the distance Dx is greater than the distance D1. Due to the aspect ratio dependent etching (ARDE) effect, the trenches 544, 545 and 546 have different depths along the Z direction. More specifically, the trench 546 is deeper than the trench 544 which is deeper than the trench 545.

The trench 546 has a portion 546a having a bottom surface 546s1 and disposed between the portion 538a of the fin 538 and the portion 539a of the fin 539. The trench 546 also has a portion 546b having a bottom surface 546s2 and disposed between the portion 538b of the fin 538 and the portion 539b of the fin 539. In an embodiment, due to the aspect ratio dependent etching (ARDE) effect, the bottom surface 546s1 is below the bottom surface 546s2. A portion 545b (shown in FIG. 12C) of the trench 545 disposed between the fin 537 and the portion 538b of the fin 538 is deeper than a portion 545a (shown in FIG. 12B) of the trench 545 disposed between the fin 537 and the portion 538a of the fin 538. In other words, the portion 545a of the trench 545 has a bottom surface 545s1, the portion 545b of the trench 545 has a bottom surface 545s2 lower than the bottom surface 545s1. The trench 544 has a bottom surface 544s. In an embodiment, a vertical distance between the bottom surface 545s2 and the bottom surface 546s2 is less than a vertical distance between the bottom surface 545s1 and the bottom surface 546s1, and a vertical distance between the bottom surface 545s2 and the bottom surface 544s is less than a vertical distance between the bottom surface 545s1 and the bottom surface 544s. The patterned first hard mask layer 504 may be selectively removed after the forming of the fins 535-539.

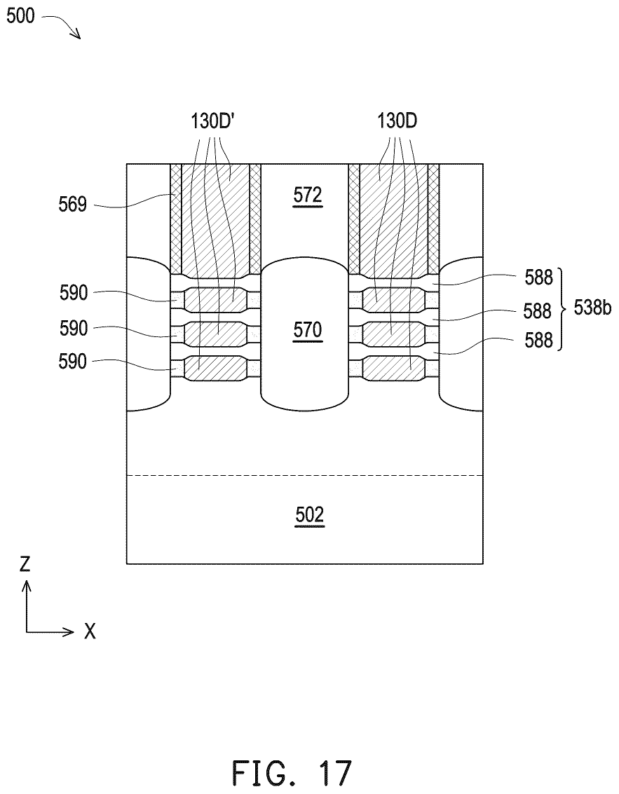

In some embodiments, as depicted herein, the fins 535-539 each include a single semiconductor layer, such as a Si layer. Alternatively, each fin 535-539 may include a multi-layer stack (ML) of alternating, different semiconductor layers over the substrate 502, where one of the semiconductor layers is considered a channel layer (e.g., such as channel layer 588 depicted in FIG. 17) and the other one is considered a non-channel layer. The non-channel layer is a sacrificial layer to be removed during a subsequent processing step, while the channel layer remains in the structure 500 and engages with a subsequently-formed metal gate structures. The channel layers and the non-channel layers have different compositions. For example, the channel layer may include Si and the non-channel layer may include SiGe. In some examples, each ML may include a total of three to ten pairs of alternating semiconductor layers. In some embodiments, forming the ML includes alternatingly growing the channel layers and the non-channel layers in a series of epitaxy processes. Each epitaxy process may include chemical vapor deposition (CVD) techniques (e.g., vapor-phase epitaxy (VPE), ultra-high vacuum CVD (UHV-CVD), low-pressure CVD (LP-CVD), and/or plasma-enhanced CVD (PECVD), molecular beam epitaxy, other suitable selective epitaxial growth (SEG) processes, or combinations thereof. Each epitaxy process may use gaseous and/or liquid precursors, which interact with the composition of the underlying substrate. In some examples, the layers of the ML may be formed as nanosheets, nanowires, or nanorods.

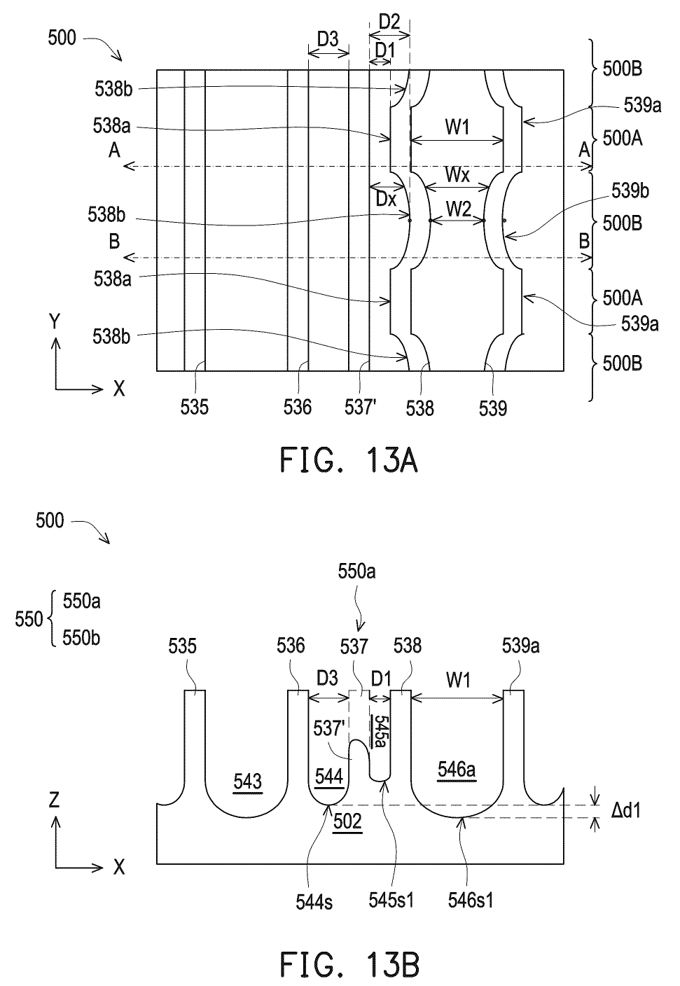

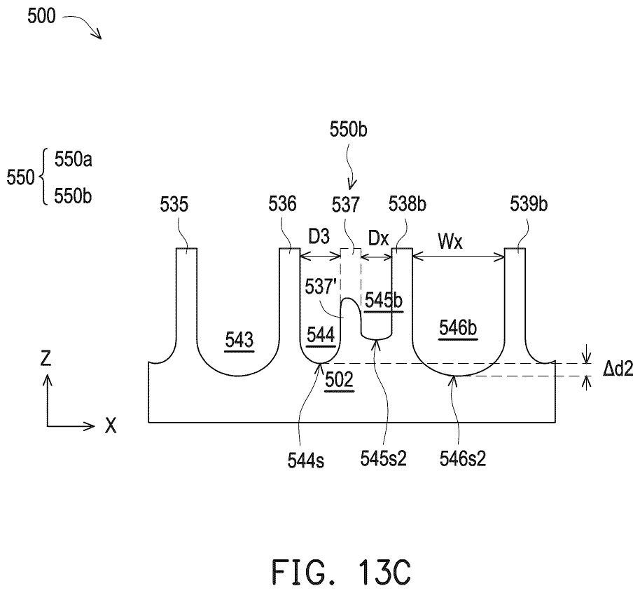

Referring now to FIGS. 4 and 13A-13C, method 400 includes a block 416 where the fin 537 is recessed. FIG. 13B depicts a fragmentary cross-sectional view of the structure 500 taken along line A-A shown in FIG. 13A, FIG. 13C depicts a fragmentary cross-sectional view of the structure 500 taken along line B-B shown in FIG. 13A. In an example process, after forming the fins 535-539, a mask layer is formed to cover the fins 535, 536, 538 and 539, while the fin 537 is not covered. An etching process is then performed to recess the fin 537. The recessed fin 537 is referred to as the fin 537′. As represented by FIGS. 13B and 13C, a top surface of the fin 537′ is lower than top surfaces of other fins 535-536 and 538-539. The fin 536 and the fin 538 is now separated by a trench 550 that extends from the fin 536 to the fin 538. More specifically, the trench 550 includes a portion 550a extending from the fin 536 to the portion 538a of the fin 538 and a portion 550b extending from the fin 536 to the portion 538b of the fin 538. A distance (i.e., the width of the trench 550) between the fin 536 and the fin 538 is a function of the distance between the fin 537 and the fin 538 and is thus non-uniform. The distance between the fin 537 and the portion 538a of the fin 538 is uniform and is equal to a sum of the distance D3, a fin width (e.g., T1) of the fin 537, and the distance D1. The distance between the fin 537 and the portion 538b of the fin 538 is varying and is equal to a sum of the distance D3, the fin width of the fin 537, and the distance Dx, where Dx is in a range between D2 and D1. That is, the distance between the fin 537 and the portion 538b of the fin 538 is greater than the distance between the fin 537 and the portion 538a of the fin 538. In addition, a distance between the portion 538a of the fin 538 and the portion 539a of the fin 539 is substantially equal to the width W1, a distance between the portion 538b of the fin 538 and the second portion 539b of the fin 539 is substantially equal to the varying width Wx, what is less than W1. As a result, the portion 550b of the trench 550 is wider and has a relative smoother bottom surface than the portion 550a of the trench 550. In an embodiment, a depth difference Δd2 between the portion 550b of the trench 550 and the portion 546b of the trench 546 is less than a depth difference Δd1 between the portion 550a of the trench 550 and the portion 546a of the trench 546. In an embodiment, a width difference between the width Wx and the width of the portion 550b of the trench 550 is less than a width difference between the width W1 and a width of the portion 550a of the trench 550.

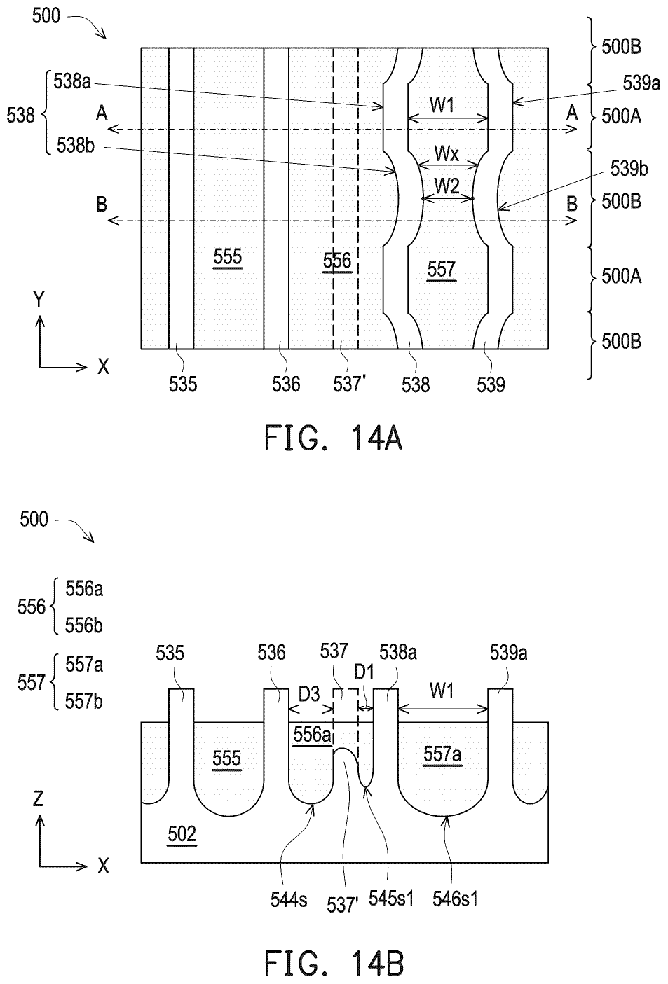

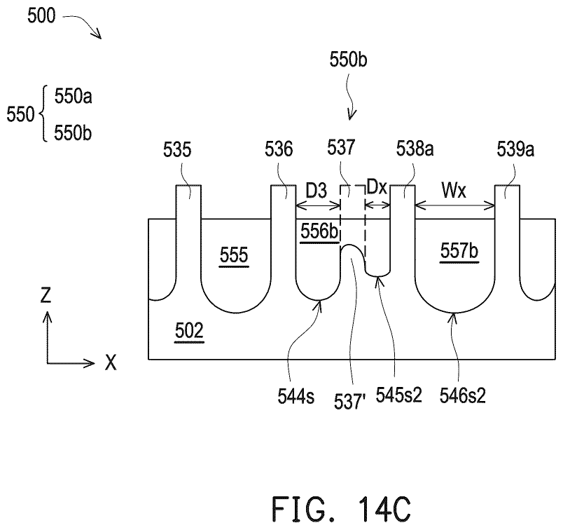

Referring now to FIGS. 4 and 14A-14C, method 400 includes a block 418 where isolation features (e.g., isolation features 555, 556, 557) are formed over the substrate 502. FIG. 14B depicts a fragmentary cross-sectional view of the structure 500 taken along line A-A shown in FIG. 14A, FIG. 14C depicts a fragmentary cross-sectional view of the structure 500 taken along line B-B shown in FIG. 14A. In an example process, a dielectric layer (not shown) is formed over the substrate 502 to fill the trenches (e.g., the trenches 543, 546, 550) between two adjacent fins. The dielectric layer may include silicon oxide, tetraethylorthosilicate (TEOS), doped silicon oxide (e.g., borophosphosilicate glass (BPSG), fluoride-doped silicate glass (FSG), phosphosilicate glass (PSG), boron-doped silicate glass (BSG), etc.), a low-k dielectric material (having a dielectric constant less than that of silicon oxide, which is about 3.9), other suitable materials, or combinations thereof and may be deposited over the structure 500 by any suitable method, such as CVD, flowable CVD (FCVD), spin-on-glass (SOG), other suitable methods, or combinations thereof. The dielectric layer may include a single-layer structure or a multi-layer structure that has a liner and fill layer on the liner. In this present embodiment, the dielectric layer is a single-layer structure. An annealing process may be applied to the structure 500 after the deposition of the dielectric layer. After deposition, the dielectric layer may subsequently be planarized by a chemical-mechanical planarization/polishing (CMP) process. An etching process is then performed to selectively recess the dielectric layer without substantially etching the fins (e.g., fins 535, 536, 538, 539) to form isolation features (e.g., isolation features 555, 556, 557). In an embodiment, top surfaces of the isolation features 555, 556, 557 are substantially coplanar.

The isolation feature 555 is disposed between the fin 535 and the fin 536, the isolation feature 556 is disposed between the fin 536 and the fin 538 and over the recessed fin 537′, and the isolation feature 557 is disposed between the fin 538 and the fin 539. The isolation feature 556 is disposed adjacent to left side of the fin 538, and the isolation feature 557 is disposed adjacent to right side of the fin 538. As represented by FIGS. 14B and 14C, the isolation feature 556 includes a portion 556a disposed between the fin 536 and the portion 538a of the fin 538 and a portion 556b disposed between the fin 536 and the portion 538b of the fin 538; and the isolation feature 557 includes a portion 557a disposed between the portion 538a of the fin 538 and the portion 539a of the fin 539 and a portion 557b disposed between the portion 538b of the fin 538 and the portion 539b of the fin 539. Each of the isolation features 555-557 track the profile of the lower portion of the corresponding trenches 543, 550, and 546, respectively. More specifically, the portion 556b of the isolation feature 556 is wider and has a relative smoother bottom surface than the portion 556a of the isolation feature 556. In an embodiment, a depth difference between the portion 556b of the isolation feature 556 and the portion 557b of the isolation feature 557 is less than a depth difference between the portion 556a of the isolation feature 556 and the portion 557a of the isolation feature 557. In an embodiment, a width difference between the portion 556a of the isolation feature 556 and the portion 557a of the isolation feature 557 is greater than a width difference between the portion 556b of the isolation feature 556 and the portion 557b of the isolation feature 557. In other words, variations (e.g., width differences, depth differences, levels of unevenness of bottom surfaces) between the portions (i.e., 556b and 557b) of the isolation features 556 and 557 formed in the second region 500B are less than variations between the portions (i.e., 556a and 557a) of the isolation features 556 and 557 formed in the first region 500A. Therefore, compared to thermal stress associated with the portions 556a and 557a of the isolation features 556 and 557, less thermal stress associated with the portions 556b and 557b of the isolation features 556 and 557 is applied to the portion 538b of the fin 538 than that of the portion 538a of the fin 538. Thus, the portion 538b of the fin 538 is less prone to cracking issues than the portion 538a of the fin 538.

Referring now to FIGS. 4 and 15A-15C, method 400 includes a block 420 where first-type isolation structures (e.g., 560 and 562) are formed to cut the fins into pieces. FIG. 15B depicts a fragmentary cross-sectional view of the structure 500 taken along line A-A shown in FIG. 15A, FIG. 15C depicts a fragmentary cross-sectional view of the structure 500 taken along line B-B shown in FIG. 15A. In this illustrated embodiment, after forming the isolation features (e.g., isolation features 555-557), isolation structures 560 and 562 are formed to cut the fin 538 and the fin 536 into pieces, respectively. Continuous poly on diffusion edge (CPODE) processes may be implemented to form the first-type isolation structures to divide active regions into segments, and the first-type isolation structures 560 and 562 may be thus referred to as CPODE structures 560 and 562 or dielectric gates 560 and 562. In this illustrated embodiment, an entirety of the portion 538a of the fin 538 is replaced by the CPODE structure 560. In an example process, an etching process is performed to selectively remove the portions 538a of the fin 538 to form isolation trenches, and then the CPODE structures 560 are then formed in the isolation trenches. A bottom surface of the CPODE structure 560 may be lower than a bottom surface 546s1. In some embodiment, only a part of the portion 538a of the fin 538 is replaced by the CPODE structure 560. The CPODE structures 560 and 562 may be formed simultaneously or in any sequential order and may be formed of one or more dielectric layers. In this illustrated embodiment, when viewed from top, the CPODE structure 560 has a uniform width and substantially straight sidewalls, and the portion 538b extends from one CPODE structure 560 to the other CPODE structure 560 and is in direct contact with the two CPODE structures 560. In an embodiment, the CPODE structure 562 is formed in the second region 500B.

Referring now to FIGS. 4 and 16A-16E, method 400 includes a block 422 where gate structures (e.g., gate structures 130A-130D and 130A′-130D′) and source/drain features 570 are formed over the substrate 502. FIG. 16A depicts a fragmentary top view of the structure 500. Some features (e.g., contacts, n-well 110, p-well 111) are omitted in FIG. 16A. FIG. 16B depicts a fragmentary cross-sectional view of the structure 500 taken along line A-A shown in FIG. 16A, FIG. 16C depicts a fragmentary cross-sectional view of the structure 500 taken along line B-B shown in FIG. 16A, FIG. 16D depicts a fragmentary cross-sectional view of the structure 500 taken along line C-C shown in FIG. 16A, and FIG. 16E depicts a simplified top view of the structure 500 shown in FIG. 16A. In an example process, after forming the fins 535-539 and the isolation features 555-557, a gate replacement process (or gate-last process) is adopted where dummy gate stacks (not shown) are formed over channel regions of the fins to serve as placeholders for functional gate structures. Other processes and configurations are possible. The dummy gate stack includes a dummy dielectric layer and a dummy gate electrode layer over the dummy dielectric layer. The dummy dielectric layer may include silicon oxide. The dummy gate electrode layer may include polysilicon. Gate spacers 569 (shown in FIG. 16D) are formed to extend along sidewall surfaces of the dummy gate stacks.

Source/drain regions of the fins (e.g., fins 535-536 and 538-539) are recessed to form source/drain openings. Source/drain features 570 are then formed in the source/drain openings. Source/drain feature(s) may refer to a source feature or a drain feature, individually or collectively dependent upon the context. Depending on the conductivity type of the to-be-formed transistor, the source/drain features 570 may be n-type source/drain features or p-type source/drain features. Exemplary n-type source/drain features may include silicon, phosphorus-doped silicon, arsenic-doped silicon, antimony-doped silicon, or other suitable material and may be in-situ doped during the epitaxial process by introducing an n-type dopant, such as phosphorus, arsenic, or antimony, or ex-situ doped using a junction implant process. Exemplary p-type source/drain features may include germanium, gallium-doped silicon germanium, boron-doped silicon germanium, or other suitable material and may be in-situ doped during the epitaxial process by introducing a p-type dopant, such as boron or gallium, or ex-situ doped using a junction implant process. Although not separately labeled, the source/drain features 570 may include multiple epitaxial semiconductor layers having different dopant concentrations.

For embodiments in which the fins 535-539 include the ML, before forming the epitaxial S/D features 570, method 400 first forms inner spacers 590 (shown in FIG. 17) on sidewalls of the non-channel layers (not depicted) exposed in the S/D recesses. The inner spacers 590 may include any suitable dielectric material SiN, SiO and/or SiO₂, SiCN, SiOC, SiON, SiOCN, a low-k dielectric material, other suitable dielectric material, or combination thereof. The inner spacers 590 may each be configured as a single-layer structure or a multi-layer structure including a combination of the dielectric materials provided herein. In some embodiments, the inner spacers 590 have a different composition from that of the gate spacers 569. The inner spacers 590 may be formed in a series of etching and deposition processes. For example, forming the inner spacers 590 may begin with selectively removing portions of the non-channel layers with respect to the channel layers 588 to form recesses (now filed by the inner spacers 590) by a suitable etching process, such as a dry etching process. Subsequently, one or more dielectric layers are formed in the trenches, followed by one or more etching processes to remove (i.e., etch back) excess dielectric layer(s) deposited on exposed surfaces of the channel layers 588, thereby forming the inner spacers 590. The one or more dielectric layers may be deposited by any suitable method, such as ALD, CVD, PVD, other suitable methods, or combinations thereof.

After forming the source/drain features 570, a dielectric structure 572 is formed over the structure 500. The dielectric structure 572 includes a contact etch stop layer (CESL) conformally disposed over the structure 500 and an interlayer dielectric (ILD) layer deposited over the CESL. In an embodiment, the CESL may include a nitride-containing dielectric material, the ILD layer may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. A planarization process, such a chemical mechanical polishing (CMP) process may be performed to the structure 500 to remove excess materials and expose top surfaces of the dummy gate electrode layers in the dummy gate stacks.

The dummy gate stacks are then replaced by functional metal gate structures (e.g., gate structures 130A-130D and 130A′-130D′ shown in FIGS. 3 and 16A). Although not separately labeled, each of the gate structures 130A-130D and 130A′-130D′ may include a gate dielectric layer and a gate electrode layer over the gate dielectric layer. In some embodiments, the gate dielectric layer includes an interfacial layer and a high-k dielectric layer over the interfacial layer. Here, a high-k dielectric layer refers to a dielectric material having a dielectric constant greater than that of silicon dioxide, which is about 3.9. In some embodiments, the interfacial layer includes silicon oxide. The high-k dielectric layer is then conformally deposited over the structure 500 using ALD, CVD, and/or other suitable methods. The high-k dielectric layer may include hafnium oxide. Alternatively, the high-k dielectric layer may include other high-k dielectrics, such as titanium oxide, hafnium zirconium oxide, tantalum oxide, hafnium silicon oxide, zirconium silicon oxide, lanthanum oxide, aluminum oxide, yttrium oxide, SrTiO₃, BaTiO₃, BaZrO, hafnium lanthanum oxide, lanthanum silicon oxide, aluminum silicon oxide, hafnium tantalum oxide, hafnium titanium oxide, (Ba,Sr)TiO₃ (BST), silicon nitride, silicon oxynitride, combinations thereof, or other suitable material. The gate electrode layer is then deposited over the gate dielectric layer using atomic layer deposition (ALD), physical vapor deposition (PVD), chemical vapor deposition (CVD), e-beam evaporation, or other suitable methods. The gate electrode layer may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer may include titanium nitride, titanium aluminum, titanium aluminum nitride, tantalum nitride, tantalum aluminum, tantalum aluminum nitride, tantalum aluminum carbide, tantalum carbonitride, aluminum, tungsten, nickel, titanium, ruthenium, cobalt, platinum, tantalum carbide, tantalum silicon nitride, copper, other refractory metals, or other suitable metal materials or a combination thereof. Further, where the structure 500 includes n-type transistors and p-type transistors, different gate electrode layers may be formed separately for n-type transistors and p-type transistors, which may include different work function metal layers (e.g., for providing different n-type and p-type work function metal layers). In an embodiment, when viewed from top, the gate structure 130A′ and the gate structure 130C′ are portions of a first continuous gate structure, the gate structure 130B′ and the gate structure 130D′ are portions of a second continuous gate structure, the gate structure 130B and the gate structure 130D are portions of a third continuous gate structure, and the gate structure 130A and the gate structure 130C are portions of a fourth continuous gate structure.

For embodiments in which the fins 535-539 include the ML, before forming the gate structures, method 400 further removes the non-channel layers from the ML during a sheet (or wire) formation process, thereby forming openings (not depicted) between the channel layers 588 (shown in FIG. 17). In the present embodiments, the sheet formation process selectively removes the non-channel layers without removing, or substantially removing, the channel layers 588. The gate structures (e.g., gate structures 130A-130D and 130A′-130D′) are further configured to wrap around the channel layers 588.

Still referring now to FIGS. 4 and 16A-16D, method 400 includes a block 424 where second-type isolation structures 576a-576b are formed to cut the continuous gate structures into pieces. In an example process, a first gate isolation trench is formed to cut both the first continuous gate structure and the second continuous gate structure into pieces, and a second gate isolation trench is formed to cut both the third continuous gate structure and the fourth continuous gate structure into pieces. A first gate isolation structure 576a and a second gate isolation structure 576b are formed in the first and second gate isolation trenches, respectively. The formation of the first and second gate isolation structures 576a and 576b may further include conformally depositing a first dielectric material over the structure and depositing a second dielectric material to fill remaining portions of the first and second gate isolation trenches, and performing a planarization process to the structure 500 to remove excess materials over the gate structures (e.g., gate structures 130A-130D and 130A′-130D′). In an embodiment, each of the first dielectric material and the second dielectric material may include silicon oxide, silicon nitride, silicon carbide, silicon oxynitride, silicon oxycarbide, silicon carbonitride, a low-k dielectric material, other suitable materials, or combinations thereof, and may be deposited by CVD, PECVD, flowable CVD, PVD, ALD, other suitable methods, or combinations thereof.

The first gate isolation structure 576a cuts the first continuous gate structure into the two electrically and physically isolated pieces (i.e., the gate structure 130A′ and the gate structure 130C′). The second gate isolation structure 576b cuts the second continuous gate structure into the two electrically and physically isolated pieces (i.e., the gate structure 130B′ and the gate structure 130D′). The second gate isolation structure 576b also cuts the third continuous gate structure into the two electrically and physically isolated pieces (i.e., the gate structure 130B and the gate structure 130D). The structure 500 may also include additional gate isolation structures. In some embodiments, the first and second gate isolation structures 576a and 576b may be referred to as cut metal gates (CMGs).

The structure 500 represented by FIG. 16A is substantially similar to the array 100 represented by FIG. 3. For example, the structure 500 includes a SRAM cell 101A′ which is similar to the cell 101A and includes the transistors PD-1′, PD-2′, PU-1′, PU-2′, PG-1′ and PG-2′. The structure 500 also includes a SRAM cell 101C′ which is similar to the cell 101C and includes the transistors PD-1, PD-2, PU-1, PU-2, PG-1 and PG-2, repeated description is omitted for reason of simplicity. One of the differences between the structure 500 and the array 100 includes that, the fins 108C and 106B shown in FIG. 3 have straight sidewalls in a top view, while the fins 538b and 539 shown in FIG. 16A include curved sidewalls. Forming the fin 538b with curved sidewalls may advantageously reduce the cracking risk.

FIG. 16E depicts a simplified top view of the structure 500. Some features (e.g., first-type and second-type isolation structures) are omitted. Compared with embodiments that include straight fins 108C and 106B, forming the fin 538b and fin 539 (or the portion 539b of the fin 539) having curved profiles would advantageously reduce thermal stress applied to the fins, thereby increasing device reliability. The methods of the present disclosure can be smoothly integrated to existing fabrication processes. For example, the fin 538b is formed in the second region 500B and disposed between two first-type isolation structures 560 that are formed in the first region 500A. Thus, landing sites of conductive features (e.g., source/drain contacts 124 and 124′, gate vias, butted contacts 126 and 126′ shown in FIG. 3) formed over or under the structure 500 will not be affected.

In the above embodiments, the structure 500 is implemented using FinFETs. In some other embodiments, the structure 500 may be implemented using GAA transistors. For example, FIG. 17 illustrates an embodiment in which the fin 538b includes the ML, where the gate structures 130D and 130D′ engage with the channel layers 588 to form a nanosheet (or GAA) FET.

Referring to FIG. 4, method 400 includes a block 426 where further processes are performed. Such further processes may include forming silicide layers and source/drain contacts electrically coupled to source/drain features 570. Such further processes may also include forming a multi-layer interconnect (MLI) structure (not depicted) over the structure 500. In some embodiments, the MLI structure may include multiple intermetal dielectric (IMD) layers and multiple metal lines or contact vias in each of the IMD layers. In some instances, the IMD layers and the ILD layer of the dielectric structure 572 may share similar composition. The metal lines and contact vias in each IMD layer may be formed of metal, such as aluminum, tungsten, ruthenium, or copper. In some embodiments, the metal lines and contact vias may be lined by a barrier layer to insulate the metal lines and contact vias from the IMD layers. Such further processes may also include forming another multi-layer interconnect (MLI) structure (not depicted) under the structure 500.

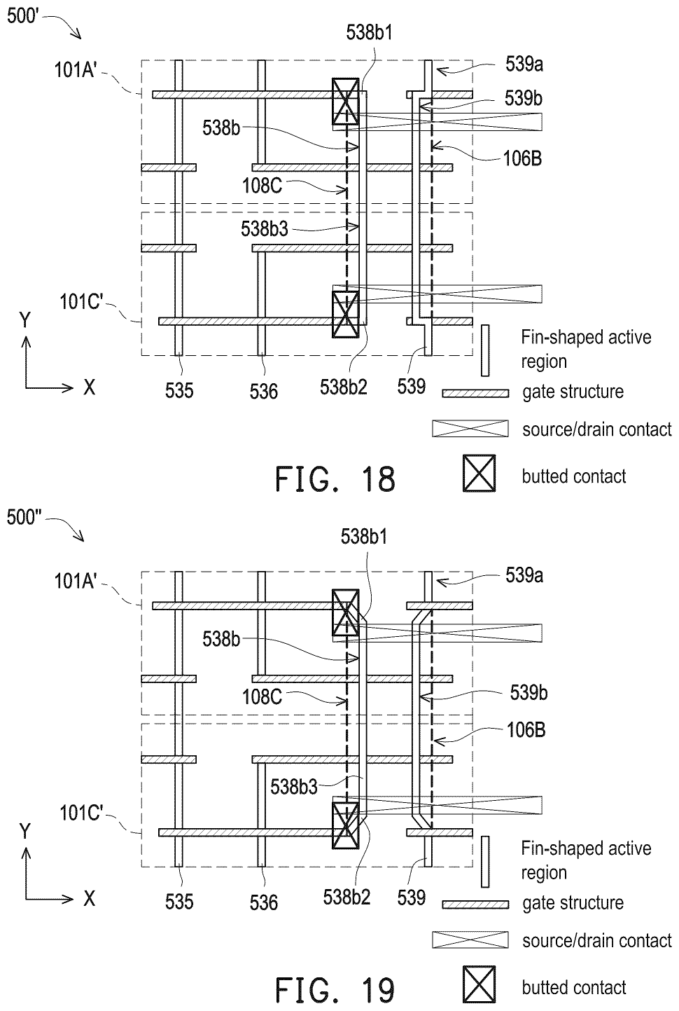

In the above embodiments, the portion 538b of the fin 538 has curved sidewalls. The portion 538b may have other profiles. FIG. 18 depicts a fragmentary layout of a first alternative structure 500′, and FIG. 19 depicts a fragmentary layout of a second alternative structure 500″. The structure 500′ and structure 500″ are substantially similar to the structure 500, except that the fin 538b and fin 539 have different profiles. For example, when viewed from top, the fin 538b of structure 500′ has a first portion 538b1 extending along the X direction, a second portion 538b2 extending along the X direction, and a third portion 538b3 extending along the Y direction and extending from the first portion to the second portion. A distance between the third portion 538b3 and the fin 536 is greater than a distance between the first portion 538b1 and the fin 536. The structure 500″ is substantially the same as the structure 500′, except that the first portion 538b1 and the portion 538b2 do not extend along the X direction. Repeated description is omitted for reason of simplicity.

Although not intended to be limiting, one or more embodiments of the present disclosure provide many benefits to an IC structure and the formation thereof. For example, the present embodiments provide methods of forming fins to alleviate fin cracking issue, thereby increasing device reliability. Embodiments of the disclosed methods can be readily integrated into existing processes and technologies for manufacturing transistors (e.g., FinFETs or GAA transistors).

The present disclosure provides for many different embodiments. Semiconductor structures and methods of fabrication thereof are disclosed herein. In one exemplary aspect, the present disclosure is directed to a method. The method includes forming a first mandrel and a second mandrel over a substrate, wherein, when viewed from top, the first mandrel has a uniform width, and the second mandrel has a varying width, forming a first spacer extending along a sidewall of the first mandrel, forming a second spacer extending along a sidewall of the second mandrel, selectively removing the first mandrel and the second mandrel, forming a first fin-shaped active region and a second fin-shaped active region protruding from the substrate, the first fin-shaped active region being disposed directly under the first spacer, and the second fin-shaped active region being disposed directly under the second spacer, wherein, when viewed from top, a distance between the first fin-shaped active region and the second fin-shaped active region is non-uniform, and recessing the first fin-shaped active region such that a top surface of the second fin-shaped active region is above a top surface of the recessed first fin-shaped active region.

In some embodiments, the method may also include, after the recessing of the first fin-shaped active region, forming an isolation feature over the substrate, the isolation feature surrounds a bottom portion of the second fin-shaped active region and has a top surface above the top surface of the recessed first fin-shaped active region. In some embodiments, when viewed from top, the second mandrel has a first segment having substantially straight sidewalls and a second segment having sidewalls curved inward. In some embodiments, when viewed from top, the second fin-shaped active region has a uniform width and comprises a first segment having substantially straight sidewalls and a second segment having curved sidewalls. In some embodiments, the method may also include replacing the first segment of the second fin-shaped active region with an isolation structure, forming a gate structure intersecting with the second segment of the second fin-shaped active region, and forming source/drain features adjacent to the gate structure and coupled to the second segment of the second fin-shaped active region. In some embodiments, the method may also include forming a mask layer over the substrate, wherein the mask layer is disposed under the first mandrel and the second mandrel, etching the mask layer using the first spacer and the second spacer as an etch mask, selectively removing the first spacer and the second spacer, and after the forming of the first fin-shaped active region and the second fin-shaped active region, selectively removing the mask layer. In some embodiments, each of the first fin-shaped active region and the second fin-shaped active region includes a single semiconductor layer. In some embodiments, each of the first fin-shaped active region and the second fin-shaped active region includes a stack of alternating first semiconductor layers and second semiconductor layers having different compositions, and the method may also include selectively removing the second semiconductor layers, and forming a gate structure wrapping around and over the first semiconductor layers. In some embodiments, the forming of the first mandrel and the second mandrel may include forming a mandrel layer over the substrate, forming a photoresist layer over the mandrel layer, and patterning the photoresist layer using a photomask, wherein the photomask comprises a first feature pattern and a second feature pattern, each of the first feature pattern and the second feature pattern having a uniform width.

In another exemplary aspect, the present disclosure is directed to a method. The method includes forming a fin-shaped active region protruding from a substrate and having a uniform width, wherein, when viewed from top, the fin-shaped active region comprises a first segment having substantially straight sidewalls and a second segment immediately adjacent to the first segment and having curved sidewalls, forming a gate structure over the second segment of the fin-shaped active region, replacing the first segment of the fin-shaped active region with an isolation structure, and forming source/drain features coupled to the second segment of the fin-shaped active region.

In some embodiments, the forming of the fin-shaped active region may include forming a mandrel layer over the substrate, forming a photoresist layer over the mandrel layer, patterning the photoresist layer, wherein the patterned photoresist layer comprises a pattern feature having a non-uniform width, patterning the mandrel layer using the patterned photoresist layer to form a mandrel, forming a spacer conformally extending along a sidewall of the mandrel, and after the forming of the spacer, performing an etching process to selectively etch the substrate. In some embodiments, a portion of the pattern feature has a profile resembling a concave lens. In some embodiments, the method may also include forming another fin-shaped active region over the substrate, wherein, when viewed from top, sidewalls of an entirety of the another fin-shaped active are substantially straight. In some embodiments, the method may also include recessing the another fin-shaped active region, a top surface of the another fin-shaped active region is lower than a top surface of the fin-shaped active region. In some embodiments, the method may also include forming an isolation feature adjacent to the fin-shaped active region and over the recessed another fin-shaped active region. In some embodiments, the second segment curves inward the most at its middle point.

In another exemplary aspect, the present disclosure is directed to a semiconductor structure. The semiconductor structure includes a first fin-shaped active region extending lengthwise along a first direction, wherein, when viewed from top, along the first direction, the first fin-shaped active region comprises a first segment having substantially straight sidewalls and a second segment immediately adjacent to the first segment and having curved sidewalls, and a second fin-shaped active region extending lengthwise along the first direction and having a first segment adjacent to the first segment of the first fin-shaped active region and a second segment adjacent to the second segment of the first fin-shaped active region, wherein, both the first and second segments of the second fin-shaped active region have substantially straight sidewalls, a distance between the second segment of the first fin-shaped active region and the second segment of the second fin-shaped active region is varying.

In some embodiments, the semiconductor structure may also include a gate structure extending lengthwise along a second direction substantially perpendicular to the first direction, where the gate structure intersects the second segments of the first and second fin-shaped active regions. In some embodiments, the semiconductor structure may also include an isolation structure extending through the first segment of the first fin-shaped active region. In some embodiments, the distance between the first segment of the first fin-shaped active region and the first segment of the second fin-shaped active region is less than the distance between the second segment of the first fin-shaped active region and the second segment of the second fin-shaped active region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first mandrel and a second mandrel over a substrate, wherein, when viewed from top, the first mandrel has a uniform width, and the second mandrel has a varying width;
forming a first spacer extending along a sidewall of the first mandrel;
forming a second spacer extending along a sidewall of the second mandrel;
selectively removing the first mandrel and the second mandrel;
forming a first fin-shaped active region and a second fin-shaped active region protruding from the substrate, the first fin-shaped active region being disposed directly under the first spacer, and the second fin-shaped active region being disposed directly under the second spacer, wherein, when viewed from top, a distance between the first fin-shaped active region and the second fin-shaped active region is non-uniform; and
recessing the first fin-shaped active region such that a top surface of the second fin-shaped active region is above a top surface of the recessed first fin-shaped active region.

2. The method of claim 1, further comprising:
after the recessing of the first fin-shaped active region, forming an isolation feature over the substrate, wherein the isolation feature surrounds a bottom portion of the second fin-shaped active region and has a top surface above the top surface of the recessed first fin-shaped active region.

3. The method of claim 1, wherein, when viewed from top, the second mandrel has a first segment having substantially straight sidewalls and a second segment having sidewalls curved inward.

4. The method of claim 1, wherein, when viewed from top, the second fin-shaped active region has a uniform width and comprises a first segment having substantially straight sidewalls and a second segment having curved sidewalls.

5. The method of claim 4, further comprising:
replacing the first segment of the second fin-shaped active region with an isolation structure;
forming a gate structure intersecting with the second segment of the second fin-shaped active region; and
forming source/drain features adjacent to the gate structure and coupled to the second segment of the second fin-shaped active region.

6. The method of claim 1, further comprising:
forming a mask layer over the substrate, wherein the mask layer is disposed under the first mandrel and the second mandrel;
etching the mask layer using the first spacer and the second spacer as an etch mask;
selectively removing the first spacer and the second spacer; and
after the forming of the first fin-shaped active region and the second fin-shaped active region, selectively removing the mask layer.

7. The method of claim 1, wherein each of the first fin-shaped active region and the second fin-shaped active region includes a single semiconductor layer.

8. The method of claim 1, wherein each of the first fin-shaped active region and the second fin-shaped active region includes a stack of alternating first semiconductor layers and second semiconductor layers having different compositions, and the method further comprises:
selectively removing the second semiconductor layers; and
forming a gate structure wrapping around and over the first semiconductor layers.

9. The method of claim 1, wherein the forming of the first mandrel and the second mandrel comprises:
forming a mandrel layer over the substrate;
forming a photoresist layer over the mandrel layer; and
patterning the photoresist layer using a photomask, wherein the photomask comprises a first feature pattern and a second feature pattern, each of the first feature pattern and the second feature pattern having a uniform width.

10. A method, comprising:
forming a fin-shaped active region protruding from a substrate and having a uniform width, wherein, when viewed from top, the fin-shaped active region comprises a first segment having substantially straight sidewalls and a second segment immediately adjacent to the first segment and having curved sidewalls;
forming a gate structure over the second segment of the fin-shaped active region;
replacing the first segment of the fin-shaped active region with an isolation structure; and
forming source/drain features coupled to the second segment of the fin-shaped active region.

11. The method of claim 10, wherein the forming of the fin-shaped active region comprises:
forming a mandrel layer over the substrate;
forming a photoresist layer over the mandrel layer;
patterning the photoresist layer, wherein the patterned photoresist layer comprises a pattern feature having a non-uniform width;
patterning the mandrel layer using the patterned photoresist layer to form a mandrel;
forming a spacer conformally extending along a sidewall of the mandrel; and
after the forming of the spacer, performing an etching process to selectively etch the substrate.

12. The method of claim 11, wherein a portion of the pattern feature has a profile resembling a concave lens.

13. The method of claim 10, further comprising:
forming another fin-shaped active region over the substrate, wherein, when viewed from top, sidewalls of an entirety of the another fin-shaped active are substantially straight.

14. The method of claim 13, further comprising:
recessing the another fin-shaped active region, wherein a top surface of the another fin-shaped active region is lower than a top surface of the fin-shaped active region.

15. The method of claim 13, further comprising:
forming an isolation feature adjacent to the fin-shaped active region and over the recessed another fin-shaped active region.

16. The method of claim 10, wherein the second segment curves inward the most at its middle point.

17. A semiconductor structure, comprising:
a first fin-shaped active region extending lengthwise along a first direction, wherein, when viewed from top, along the first direction, the first fin-shaped active region comprises a first segment having substantially straight sidewalls and a second segment immediately adjacent to the first segment and having curved sidewalls; and
a second fin-shaped active region extending lengthwise along the first direction and having a first segment adjacent to the first segment of the first fin-shaped active region and a second segment adjacent to the second segment of the first fin-shaped active region, wherein, both the first and second segments of the second fin-shaped active region have substantially straight sidewalls,
wherein, a distance between the second segment of the first fin-shaped active region and the second segment of the second fin-shaped active region is varying.

18. The semiconductor structure of claim 17, further comprising:
a gate structure extending lengthwise along a second direction substantially perpendicular to the first direction, wherein the gate structure intersects the second segments of the first and second fin-shaped active regions.

19. The semiconductor structure of claim 17, further comprising:
an isolation structure extending through the first segment of the first fin-shaped active region.

20. The semiconductor structure of claim 17, wherein a distance between the first segment of the first fin-shaped active region and the first segment of the second fin-shaped active region is less than the distance between the second segment of the first fin-shaped active region and the second segment of the second fin-shaped active region.
